(19) United States
(12) Patent Application Publication
(10) Pub. No.: US 2004/0004271 A1
(43) Pub. Date: Jan. 8, 2004

(54) Semiconductor substrate and method for fabricating the same

(75) Inventors: Tetsuo Fukuda, Kawasaki (JP); Katsushi Hirata, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/607,013

(22) Filed: Jun. 27, 2003

(30) Foreign Application Priority Data
Jul. 1, 2002 (JP) 2002-192133

(51) Int. Cl. H01L 29/04; H01L 21/302

(52) U.S. Cl. 257/616; 438/752; 257/627; 257/628

(57) ABSTRACT

The semiconductor substrate comprises a silicon substrate 10, a silicon germanium layer 12 formed on the silicon substrate; and a silicon layer 14 formed on the silicon germanium layer. At least one of an isotope composition ratio of one Si isotope and an isotope composition ratio of a Ge isotope of at least one of the silicon substrate, the silicon germanium layer and the silicon layer is above 95%. In at least one of the silicon substrate, the silicon germanium layer and the silicon layer, at lest one of an isotope composition ratio of one Si isotope and an isotope composition ratio of one Ge isotope is set higher, whereby the heat can be scattered in the direction horizontal to the substrate plane. Thus, the semiconductor substrate can have higher heat radiation.

### CROSS-REFERENCE TO RELATED APPLICATION

This application is based upon and claims priority of Japanese Patent Application No.2002-192133, filed on Jul. 1, 2002, the contents being incorporated herein by reference.

### BACKGROUND OF THE INVENTION

The present invention relates to a semiconductor substrate and a method for fabricating the semiconductor substrate, more specifically a semiconductor substrate which can improve heat radiation and a method for fabricating the semiconductor substrate.

Improvements for higher speed have been continuously made on MOSFETs (Metal Oxide Semiconductor-Field Effect Transistors) etc. by micronizing elements, typically reducing the gate length.

A propagation delay time τ of a signal in a MOSFET is expressed by the following formula.

τ=C_{load}·V_{dd}/[{W·μ·ε)/(L·T_{OX})}×(V_{dd}−Vₜ)²] (1)

wherein C_{load} represents a load capacitance; V_{dd} represents a source voltage; W represents a gate width of the MOSFET; L represents a gate length of the MOSFET; μ represents a carrier mobility; ε represents a dielectric constant of the gate insulation film; T_{OX} represents a thickness of the gate insulation film; and Vₜ represents a threshold voltage.

Based on the above-described formula, it can be seen that a transistor is micronized, specifically a gate length L is shortened, whereby higher speed can be realized. However, in order to fabricate an ultramicronized transistor having a below 70 nm-gate length, an optical aligner having a light source of a 157 nm-wavelength F₂ excimer laser is necessary. One optical aligner using an F₂ excimer laser light source is as expensive as 2-3 billions. A plurality of such expensive aligners are necessary to constitute a fabrication line, which requires vast investment.

Based on the above-described formula, it can be seen that higher speed of the MOSFET can be realized by increasing a source voltage V_{dd}. However, the electric power consumption of the MOSFET increases in proportion of a square of a source voltage (Reference 1: T. Tsuchiya, Oyo Butsuri 66, 1191 (1997)). In consideration of high integration, it is not preferable to increase a source voltage.

Based on the above-described formula, it can be seen that higher speed of the MOSFET can be realized also by decreasing a film thickness T_{OX} of the gate insulation film. However, the thermal oxide film of a 1.5 nm-thickness has been already developed, and it is very difficult to further thin the gate insulation film.

Based on the above-described formula, it can be seen that higher speed of the MOSFET can be realized also by increasing a dielectric constant ε of the gate insulation film. However, the gate insulation film of high dielectric constant ε has a number of problems for the practical use and takes much time to be practically used.

Based on the above-described formula, it can be seen that higher speed of the MOSFET can be realized also by decreasing a load capacitance C_{load}. It is not easy to further improve values of the above-described other parameters, and techniques of decreasing a value of the load capacitance C_{load} are noted.

As a technique of decreasing a load capacitance of the MOSFET, SOI (Silicon On Insulator) substrates are proposed. The SOI substrates have the structure that a silicon crystal layer for semiconductor elements to be fabricated on is spaced from a silicon crystal substrate by a buried oxide film. In a case that the MOSFET is fabricated, using an SOI substrate, a junction capacitance between the source and the drain is decreased by about 1/10 in comparison with a case that the MOSFET is fabricated using a usual CZ wafer (see Reference 1), and the wiring capacitance is decreased by several dozen % (see Reference 2: Y. Yamaguchi, et al., IEEE Trans. Electron Devices 40, 179 (1993)). The parasitic capacitance C_{load} of the MOSFET can be decreased by using an SOI substrate. Accordingly, the operational speed of the MOSFET can be increased by using the SOI substrate.

It is reported that a band structure of a silicon crystal layer is changed when a silicon crystal layer is crystal strained, and a mobility of electrons and holes in the silicon crystal layer is increased (see Reference 3: G. Abstreiter, et. al., Phys. Rev. Lett. 54, 2441 (1985) and Reference 4: D. K. Nayak, et al., Appl. Phys. Lett. 62, 2853 (1993)).

Recently, a semiconductor substrate of the strained Si/SiGe structure is proposed. The semiconductor substrate of the strained Si/SiGe structure comprises on a silicon crystal substrate a silicon germanium crystal layer of, e.g., a 10-30% Ge concentration and a several dozen—several hundred nm-thickness silicon germanium crystal layer, and a silicon crystal layer formed on the silicon germanium crystal layer (Reference 5: K. K. Linder, et al., Appl. Phys. Lett. 70, 3224 (1997)). Because Si and Ge, which have properties of solid solution of all composition ratio, a silicon genermanium crystal layer is an alloy even in any ratio of Si to Ge. Because the covalent radius of a Ge atom is larger by some percentages than that of an Si atom, the interstitial mean distance of a silicon germanium crystal layer is larger than that of a silicon crystal layer. Accordingly, when the silicon crystal layer is formed on the silicon germanium crystal layer, crystal strains are caused in the silicon crystal layer.

A technique that a Ge concentration in the silicon germanium crystal layer is decreased gradually to the side of the silicon crystal substrate to thereby decrease a dislocation density of the silicon germanium crystal layer is also proposed (Reference 6: E. A. Fitzgerald, et al., Appl. Phys. Lett. 59, 811 (1991)).

Thus, a semiconductor substrate of the strained Si/SiGe structure is used to thereby increase a carrier mobility of the silicon crystal layer, whereby the MOSFET can have higher operation speed.

Recently, semiconductor substrates of the strained Si/SiGeOI structure are proposed (Reference 7: A. R. Powell, et al., Appl. Phys. Lett. 64, 1856 (1994) and Reference 8: Y. Ishikawa, et al., Appl. Phys. Lett. 75, 983 (1999)). The semiconductor substrate of the strained Si/SiGeOI structure comprises a layer of a silicon germanium crystal layer and a silicon crystal layer spaced from a silicon crystal substrate by a buried oxide film.

A semiconductor substrate of the strained Si/SiGeOI structure is fabricated as exemplified below.

That is, first, a silicon germanium crystal layer of, e.g., a 1 μm-thickness Si_{0.9}Ge_{0.1} is epitaxially grown on a silicon crystal substrate. At this time, a Ge concentration in the 850 nm-region of the silicon germanium layer, which is nearer to the lower layer is set to lower gradually to the side of the silicon crystal substrate.

Next, oxygen ions are implanted at a 170 keV acceleration energy and a 3×10¹⁷ cm⁻² dose. Then, thermal processing is performed at an above-1300° C. temperature and for 6 hours. Then, the buried oxide film of a 110 nm-thickness is formed in the silicon germanium crystal layer.

Then, the oxide film formed on the silicon germanium crystal layer is removed by using a hydrofluoric acid solution while the surface of the silicon germanium crystal layer is terminated with hydrogen.

Next, a silicon germanium crystal layer of, e.g., 150 nm-thickness Si_{0.9}Ge_{0.1}, and a silicon crystal layer of, e.g., a 15 nm-thickness are sequentially epitaxially grown. A thickness of the silicon germanium crystal layer on the buried oxide film and a thickness of the silicon crystal layer is totally about, e.g., 600 nm.

Thus, the semiconductor substrate of the strained Si/SiGeOI is fabricated.

The semiconductor substrate of the thus-fabricated semiconductor structure has, in comparison with the usual SOI substrate, the electron mobility increased about 60% (see Reference 9: T. Mizuno, et al., IEEE Electron Device Lett. EDL-21, 230 (2000) and the hole mobility by about 18% (see Reference 10: T. Mizuno et al., Tech. Dig. Int. Electron, Devices Meet., Washington, 1999, p. 934). Accordingly, the use of the semiconductor substrate of the strained Si/SiGeOI structure can further increase the operation speed of MOS transistors.

Here, it is very important in micronized integrated circuits that Joule's heat generated during their operation is effectively scattered. Then, this will be explained by means of a microprocessor, which is a typical high-end ultrafast device.

Millions—ten millions MOSFETs are formed in the core part of the microporcessor. When the MOSFETs are operated, the drain current causes Joule's heat. The core part is concentrated in only 5-10% of region of a semiconductor chip, and a temperature of the core part of a most advanced microprocessor rises to above 100° C. (see Reference 11: S. J. Burden, SEMICONDUCTOR FABTECH, Mar., 2001, 13th Edition, p. 297). Thus, it is very important to scatter Joule's heat generated in the core part.

As integrated circuits are more micronized, size deviations of the source/drains, dopant concentration deviations, contact resistance deviations, etc. are conspicuous due to deviations of processing for etching, ion implantation, etc. Topography of the surfaces of semiconductor substrates are a factor for deviations in the miconization. Such deviations cause parts where Joule's heat is much generated, in locations called hot spots (see Reference 11). The temperature rise is a factor for low reliability of the integrated circuits. It is very important to effectively scatter Joule's heat generated in the hot spots.

It is very important to effectively scatter Joule's heat generated in the core part or the hot spot, etc., in order to improve the operation speed of a integrated circuit without causing a decline of reliability.

However, the above-described SOI substrate, strained Si/SiGe semiconductor substrate and strained Si/SiGeOI semiconductor substrate lower the heat radiation in comparison with the usual CZ wafer and epitaxial wafer as will be described below.

Generally, the thermal conductivity of Si crystals is about 150 W/mK at a 300 K temperature (Reference 12: Y. S. Touloukian, et al., Thermophysical Properties of Matter 2, Thermal Conductivity, Nonmetallic Solids, Plenum (1970)). The thermal conductivity of Ge crystals is about 60-77W at a 300 K temperature (see Reference 13: M. A. Palmer, et al., Phy. Rev. B 56, 9431 (1997)). The thermal conductivity of silicon oxide film is about 1.38 at a 300 K temperature (see Reference 13). However, because the thermal conductivity of silicon oxide film is unknown, the thermal conductivity of quartz glass is shown here. The thermal conductivity of quartz glass is the generally used approximation.

Based on the above, the thermal conductivity of silicon oxide film is about 1/100 of that of the silicon crystals. Accordingly, in the SOI substrate, a heat radiation amount of Joule's heat generated in the silicon crystal layer and radiated in the direction of depth of the SOI substrate will be about 1/100 in comparison with heat radiation amounts of the CZ wafer, etc.

Based on the above, the thermal conductivity of Ge crystals is about ½ of that of Si crystals, based on which the thermal conductivity of SiGe crystals will be lower than that of Si crystals. Accordingly, in the strained Si/SiGe structure semiconductor substrate, a heat radiation amount of Joule's heat generated in the silicon crystal layer and radiated in the direction of depth of the strained Si/SiGe structure will be smaller in comparison with heat radiation amount of the CZ wafer, etc.

In the strained Si/SiGeOI structure semiconductor substrate, three layers, a silicon germanium crystal layer, a buried oxide film and a silicon germanium crystal layer are formed below a silicon crystal layer. It is evident that in the strained Si/SiGeOI structure semiconductor substrate, a heat radiation amount of Joule's heat generated in the silicon crystal layer and radiated in the direction of depth of the strained Si/SiGeOI structure semiconductor substrate is further smaller than that of the SOI substrate described above.

As described above, the heat radiation of the SOI substrate, the strained Si/SiGe structure semiconductor substrate and the strained Si/SiGeOI structure semiconductor substrate is lower in comparison with the usual CZ wafer, etc. Techniques which can improve the heat radiation of the SOI substrate, the strained Si/SiGe structure semiconductor substrate, and the strained Si/SiGeOI structure semiconductor substrate have been expected.

### SUMMARY OF THE INVENTION

An object of the present invention is to provide a semiconductor substrate which can improve the heat radiation and a method for fabricating the semiconductor substrate.

According to one aspect of the present invention, there is provided a semiconductor substrate comprising a silicon substrate; a silicon germanium layer formed on the silicon substrate; and a silicon layer formed on the silicon germanium layer, at least one of an isotope composition ratio of one Si isotope and an isotope composition ratio of one Ge isotope of at least one of the silicon substrate, the silicon germanium layer and the silicon layer being above 95%.

According to another aspect of the present invention, there is provided a semiconductor substrate comprising a silicon germanium substrate; and a silicon layer formed on the silicon germanium substrate, at lest one of an isotope composition ratio of one Si isotope and an isotope composition ratio of one Ge isotope of at least one of the silicon germanium substrate and the silicon layer being above 95%.

According to further another aspect of the present invention, there is provided a semiconductor substrate comprising a base substrate and a silicon layer bonded to each other with an insulation film formed therebetween, an isotope composition ratio of one Si isotope of at least one of the base substrate and the silicon layer being above 95%.

According to further another aspect of the present invention, there is provided a semiconductor substrate comprising a base substrate; a silicon germanium layer formed on the base substrate with an insulation film formed therebetween; and a silicon layer formed on the silicon germanium layer, one of an isotope composition ratio of one Si isotope and an isotope composition ratio of one Ge isotope of at least one of the silicon germanium layer and the silicon layer being above 95%.

According to further another aspect of the present invention, there is provided a method for fabricating a semiconductor substrate comprising the steps of: forming a silicon germanium layer on a silicon substrate, and forming a silicon layer on the silicon germanium layer, the silicon germanium layer or the silicon layer being formed by using a raw material gas in which at least one of an isotope composition ratio of one Si isotope and an isotope composition ratio of one Ge isotope is above 95% in at least one of the step of forming a silicon germanium layer and the step of forming a silicon layer.

According to further another aspect of the present invention, there is provided a method for fabricating a semiconductor substrate comprising the step of forming a silicon layer on a silicon germanium substrate, the silicon layer being formed by using a raw material gas having an above 95% isotope composition ratio of one Si isotope in the step of forming the silicon layer.

According to further another aspect of the present invention, there is provided a method for fabricating a semiconductor substrate comprising the step of: forming an insulation film on one surface of a silicon substrate having an above 95% isotope composition ratio of one Si isotope; bonding the insulation film to a base substrate; and thinning the silicon substrate at the other surface of the silicon substrate.

According to further another aspect of the present invention, there is provided a method for fabricating a semiconductor substrate comprising the steps of: forming a silicon layer on one surface of a silicon substrate by using a raw material gas having an 95% isotope composition ratio of one Si isotope; forming an insulation film on the silicon layer; bonding a base substrate to the insulation film; and thinning the silicon substrate at the other surface of the silicon substrate.

According to further another aspect of the present invention, there is provided a method for fabricating a semiconductor substrate comprising the steps of: bonding a silicon substrate to a base substrate with an insulation film formed therebetween, thinning the silicon substrate on the side of the silicon substrate; forming a silicon germanium layer on said thinned silicon substrate; and the step of forming a silicon layer on the silicon germanium layer, the silicon germanium layer or the silicon layer being formed by using a raw material gas in which at least one of an isotope composition ratio of one Si isotope and an isotope composition ratio of one Ge isotope is above 95% in at least one of the step of forming a silicon germanium layer and the step of forming a silicon layer.

According to further another aspect of the present invention, there is provided a method for fabricating a semiconductor substrate comprising the steps of: burying an insulation film in a silicon substrate; forming a silicon germanium layer on the silicon substrate with the insulation film buried in; and forming a silicon layer on the silicon germanium layer, the silicon germanium layer or the silicon layer being formed by using a raw material gas in which at least an isotope composition ratio of one Si isotope and an isotope composition ratio of one Ge isotope is above 95% in at least one of the step of forming a silicon germanium layer and the step of forming a silicon layer.

According to further another aspect of the present invention, there is provided a method for fabricating a semiconductor substrate comprising the steps of: forming a silicon germanium layer on a silicon substrate; forming a silicon layer on the silicon germanium layer; and burying an insulation film in the silicon substrate, the silicon germanium layer or the silicon layer being formed by using a raw material gas in which at least one of an isotope composition ratio of an Si isotope and an isotope composition ratio of a Ge isotope is above 95% in at lest one of the step of forming a silicon germanium layer and the step of forming a silicon layer.

According to further another aspect of the present invention, there is provided a method for fabricating a semiconductor substrate comprising the steps of: forming a silicon germanium layer on a silicon substrate; burying an insulation film in the silicon substrate; and forming a silicon layer on the silicon germanium layer, the silicon germanium layer or the silicon layer being formed by using a raw material gas in which at least one of an isotope composition ratio of an Si isotope and an isotope composition ratio of a Ge isotope is above 95% in at least one of the step of forming a silicon germanium layer and the step of forming a silicon layer.

According to the present invention, in the silicon crystal layer, the silicon germanium crystal layer, the silicon crystal substrate, etc., the isotope composition ratio of any one of the Si isotopes and the isotope composition ratio of any one of the Ge isotopes are set very high, whereby the thermal conductivities of the silicon crystal layer, the silicon germanium crystal layer, the silicon crystal substrate, etc. can be higher. Thus, according to the present invention, the heat radiation can be enhanced in the direction horizontal to the substrate plane. Accordingly, in the present invention, the heat generated from the core parts, hot spots, etc. of microprocessors can be effectively radiated. The present invention can provide a semiconductor substrate having the heat radiation improved, and accordingly can contribute to faster operations and higher reliability of high end ultrafast devices, etc.

### BRIEF DESCRIPTION OF THE DRAWINGS

FIG. 1 is a sectional view of the semiconductor substrate according to a first embodiment of the present invention.

FIGS. 2A to 2C are sectional views of the semiconductor substrate according to the first embodiment in the steps of the method for fabricating the semiconductor substrate, which explain the method.

FIG. 3 is a sectional view of the semiconductor substrate according to a second embodiment of the present invention.

FIGS. 4A to 4C are sectional views of the semiconductor substrate according to the second embodiment of the present invention in the steps of the method for fabricating the semiconductor substrate, which explain the method.

FIG. 5 is a sectional view of the semiconductor substrate according to a third embodiment of the present invention.

FIGS. 6A to 6C are sectional views of the semiconductor substrate according to the third embodiment in the steps of the method for fabricating the semiconductor substrate, which explain the method.

FIG. 7 is a sectional view of the semiconductor substrate according to a fourth embodiment of the present invention.

FIGS. 8A and 8B are sectional views of the semiconductor substrate according to the fourth embodiment in the steps of the method for fabricating the semiconductor substrate, which explain the method.

FIG. 9 is a sectional view of the semiconductor substrate according to a fifth embodiment of the present embodiment.

FIGS. 10A to 10C are sectional views of the semiconductor substrate according to the fifth embodiment of the present invention in the steps of the method for fabricating the semiconductor substrate, which explain the method (Part 1).

FIGS. 11A and 11B are sectional views of the semiconductor substrate according to the fifth embodiment of the present invention in the steps of the method for fabricating the semiconductor substrate, which explain the method (Part 2).

FIGS. 12A to 12C are sectional views of the semiconductor substrate in the steps of method for fabricating the semiconductor substrate according to a modification of the fifth embodiment of the present invention, which explain the method (Part 1).

FIGS. 13A and 13B are sectional views of the semiconductor substrate in the steps of method for fabricating the semiconductor substrate according to a modification of the fifth embodiment of the present invention, which explain the method (Part 2).

FIG. 14 is a sectional view of the semiconductor substrate according to a sixth embodiment of the present invention.

FIGS. 15A to 15C are sectional views of the semiconductor substrate according to the sixth embodiment in the steps of the method for fabricating the semiconductor substrate, which show the method (Part 1).

FIGS. 16A to 16C are sectional views of the semiconductor substrate according to the sixth embodiment in the steps of the method for fabricating the semiconductor substrate, which show the method (Part 2).

FIGS. 17A to 17C are sectional views of the semiconductor substrate in the steps of method for fabricating the semiconductor substrate according to Modification 1 of the sixth embodiment of the present invention, which explain the method (Part 1).

FIGS. 18A to 18C are sectional views of the semiconductor substrate in the steps of method for fabricating the semiconductor substrate according to Modification 1 of the sixth embodiment of the present invention, which explain the method (Part 2).

FIGS. 19A to 19C are sectional views of the semiconductor substrate in the steps of method for fabricating the semiconductor substrate according to Modification 2 of the sixth embodiment of the present invention, which explain the method.

FIGS. 20A to 20D are sectional views of the semiconductor substrate in the steps of method for fabricating the semiconductor substrate according to Modification 3 of the sixth embodiment of the present invention, which explain the method.

FIGS. 21A to 21C are sectional views of the semiconductor substrate in the steps of method for fabricating the semiconductor substrate according to Modification 4 of the sixth embodiment of the present invention, which explain the method (Part 1).

FIGS. 22A and 22B are sectional views of the semiconductor substrate in the steps of method for fabricating the semiconductor substrate according to Modification 4 of the sixth embodiment of the present invention, which explain the method (Part 2).

FIGS. 23A to 23C are sectional views of the semiconductor substrate in the steps of method for fabricating the semiconductor substrate according to Modification 5 of the sixth embodiment of the present invention, which explain the method.

FIG. 24 is a sectional view of the semiconductor substrate according to a seventh embodiment of the present invention.

FIGS. 25A to 25C are sectional views of the semiconductor substrate according to the seventh embodiment in the steps of the method for fabricating the semiconductor substrate, which show the method (Part 1).

FIGS. 26A to 26C are sectional views of the semiconductor substrate according to the seventh embodiment in the steps of the method for fabricating the semiconductor substrate, which show the method (Part 2).

FIG. 27 is a sectional view of the semiconductor substrate according to an eighth embodiment of the present invention.

FIGS. 28A to 28C are sectional views of the semiconductor substrate according to the eighth embodiment in the steps of the method for fabricating the semiconductor substrate, which show the method.

FIG. 29 is a sectional view of the semiconductor substrate according to a ninth embodiment of the present invention.

FIGS. 30A to 30C are sectional views of the semiconductor substrate according to the ninth embodiment in the steps of the method for fabricating the semiconductor substrate, which show the method.

FIG. 31 is a sectional view of the semiconductor substrate according to a tenth embodiment of the present invention.

FIGS. 32A to 32C are sectional views of the semiconductor substrate according to the tenth embodiment in the steps of the method for fabricating the semiconductor substrate, which show the method (Part 1).

FIGS. 33A to 33C are sectional views of the semiconductor substrate according to the tenth embodiment in the steps of the method for fabricating the semiconductor substrate, which show the method (Part 2).

FIGS. 34A to 34C are sectional views of the semiconductor substrate in the steps of method for fabricating the semiconductor substrate according to Modification 1 of the tenth embodiment of the present invention, which explain the method (Part 1).

FIGS. 35A to 35C are sectional views of the semiconductor substrate in the steps of method for fabricating the semiconductor substrate according to Modification 1 of the tenth embodiment of the present invention, which explain the method (Part 2).

FIGS. 36A to 36C are sectional views of the semiconductor substrate in the steps of method for fabricating the semiconductor substrate according to Modification 2 of the tenth embodiment of the present invention, which explain the method (Part 1).

FIGS. 37A to 37C are sectional views of the semiconductor substrate in the steps of method for fabricating the semiconductor substrate according to Modification 2 of the tenth embodiment of the present invention, which explain the method (Part 2).

FIG. 38 is a sectional view of the semiconductor substrate according to an eleventh embodiment of the present invention.

FIGS. 39A to 39C are sectional views of the semiconductor substrate according to the eleventh embodiment in the steps of the method for fabricating the semiconductor substrate, which show the method.

FIGS. 40A to 40C are sectional views of the semiconductor substrate in the steps of method for fabricating the semiconductor substrate according to Modification 1 of the eleventh embodiment of the present invention, which explain the method (Part 1).

FIGS. 41A to 41C are sectional views of the semiconductor substrate in the steps of method for fabricating the semiconductor substrate according to Modification 1 of the eleventh embodiment of the present invention, which explain the method (Part 2).

FIGS. 42A to 42C are sectional views of the semiconductor substrate in the steps of method for fabricating the semiconductor substrate according to Modification 2 of the eleventh embodiment of the present invention, which explain the method (Part 1).

FIGS. 43A to 43C are sectional views of the semiconductor substrate in the steps of method for fabricating the semiconductor substrate according to Modification 2 of the eleventh embodiment of the present invention, which explain the method (Part 2).

FIG. 44 is a sectional view of the semiconductor substrate according to a twelfth embodiment of the present invention.

FIGS. 45A to 45C are sectional views of the semiconductor substrate according to the twelfth embodiment in the steps of the method for fabricating the semiconductor substrate, which show the method.

FIGS. 46A to 46C are sectional views of the semiconductor substrate in the steps of method for fabricating the semiconductor substrate according to Modification 1 of the twelfth embodiment of the present invention, which explain the method (Part 1).

FIGS. 47A to 47C are sectional views of the semiconductor substrate in the steps of method for fabricating the semiconductor substrate according to Modification 1 of the twelfth embodiment of the present invention, which explain the method (Part 2).

FIGS. 48A to 48C are sectional views of the semiconductor substrate in the steps of method for fabricating the semiconductor substrate according to Modification 2 of the twelfth embodiment of the present invention, which explain the method (Part 1).

FIGS. 49A to 49C are sectional views of the semiconductor substrate in the steps of method for fabricating the semiconductor substrate according to Modification 2 of the twelfth embodiment of the present invention, which explain the method (Part 2).

### DETAILED DESCRIPTION OF THE INVENTION

[The Principle of the Invention]

The principle of the present invention will be explained before embodiments of the present invention are explained.

As described above, improvement of the heat radiation is a problem of the SOI substrate, semiconductor substrates of the strained Si/SiGe structure and semiconductor substrates of the strained Si/SiGeOI structure.

The inventors of the present invention have made earnest studies and got an idea that an isotope composition ratio of any one of ²⁸Si, ²⁹Si, ³⁰Si and an isotope ratio of ⁷⁰Ge, ⁷²Ge, ⁷³Ge, ⁷⁴Ge and ⁷⁶Ge of a silicon crystal layer, a silicon germanium crystal layer, etc., are set to be high, whereby the heat radiation of a semiconductor substrate can be improved.

The usual silicon crystal is composed of three kinds of isotopes, ²⁸Si, ²⁹Si and ³⁰Si. ²⁸Si is Si whose mass number is 28; ²⁹Si is Si whose mass number is 29; and ³⁰Si is Si whose mass number is 30. The isotope abundance ratios of Si in nature is 92.2% of ²⁸Si, 4.7% of ²⁹Si and 3.1% of ³⁰Si, and are always constant (Reference 14: W. S. Capinski et al., Appl. Phys. Lett. 71, 2109 (1997)).

The thermal conductivity of such usual silicon crystal is, as described above, about 150 W/mK at, e.g., 300 K (see Reference 12).

In contrast to this, when an isotope composition ratio of, e.g., ²⁸Si is set as high as 99.86%, the thermal conductivity of the silicon crystal is about 237 W/mK at, e.g., 300 K (see Reference 15: T. Ruf, et al., Solid State Commum., 115, 243 (2000)).

Based on this, it can be seen that an isotope composition ratio of Si is set very high, whereby the thermal conductivity of the silicon crystal can be raised by about 58%.

In a silicon crystal, an isotope composition ratio of any one of the Si isotopes is set high, whereby the thermal conductivity of the usual silicon crystal can be higher. The mechanism for this will be as follows.

That is, the thermal conduction is a phenomena that lattice vibrations (phonons) excited by heat propagate in waves from a higher-temperature part to a lower temperature part. When all the atoms in a crystal lattice have the same mass, an idealistic progressive waves can be formed. In contrast to this, in a system where a plurality of isotopes are present, progressive waves are scattered, and the thermal conductivity is lowered.

The increase of the thermal conductivity will be due to such mechanism. Not only when an isotope composition ratio of ²⁸Si set high, but also when isotope ratios of ²⁹Si and ³⁰Si are set high, the thermal conductivity will be similarly increased.

A usual Ge crystal is composed of five kinds of isotope elements, ⁷⁰Ge, ⁷²Ge, ⁷³Ge, ⁷⁴Ge and ⁷⁶Ge. ⁷⁰Ge is Ge whose mass number is 70; ⁷²Ge is Ge whose mass number is 72; ⁷⁴Ge is Ge whose mass number is 74; and ⁷⁶Ge is Ge whose mass number is 76. The isotope abundance ratios of ⁷⁰Ge, ⁷²Ge, ⁷³Ge ⁷⁴Ge and ⁷⁶Ge are always constantly 20.5%, 27.4%, 7.8%, 36.5% and 7.8% respectively.

The thermal conductivity of such usual Ge crystal is about 60-77 W/mK at, e.g., a temperature of 300K (see Reference 13).

In contrast to this, when an isotope composition ratio of, e.g., ⁷⁰Ge is set to be 99.99%, the thermal conductivity of Germanium crystal is about 100 W/mK at 300K (see Reference 13).

Based on the above, an isotope composition ratio of ⁷⁰Ge is set very high, whereby the thermal conductivity of germanium crystal can be increased by about 30-67%.

The mechanism that in germanium crystal, an isotope composition ratio of any one of the Ge isotopes is set high, whereby the thermal conductivity is increased than that of the usual germanium crystal will be the same as that of silicon crystal described above.

Thus, not only when an isotope abundance ratio of ⁷⁰Ge is set high, but also when an isotope abundance ratio of ⁷²Ge, ⁷³Ge, ⁷⁴Ge or ⁷⁶Ge is set high, the thermal conductivity will be able to be similarly increased.

The inventors of the present application, based on such results of their studies, have got an idea that an isotope composition ratio of any one of the Si isotopes and an isotope composition ratio of any one of the Ge isotopes of a silicon crystal layer and a silicon germanium crystal layer are set high, whereby thermal conductivities of the silicon crystal layer and the silicon germanium layer can be increased, and the heat can be scattered more in the direction horizontal to the substrate plane, which enables a semiconductor substrate having good heat radiation to be provided.

[A First Embodiment]

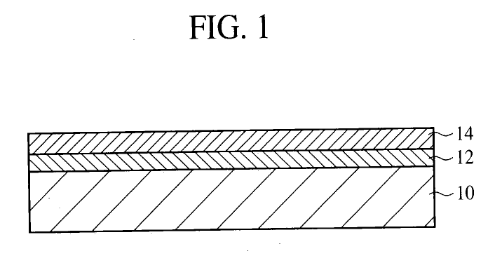

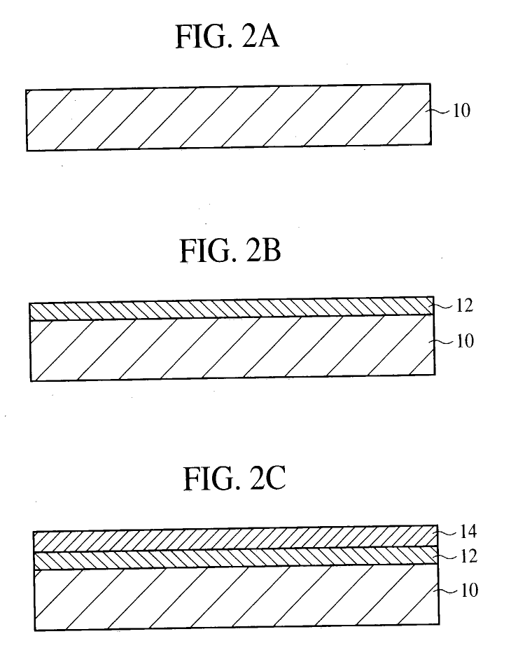

The semiconductor substrate according to a first embodiment of the present invention and the method for fabricating the semiconductor substrate will be explained with reference to FIGS. 1 to 2C. FIG. 1 is a sectional view of the semiconductor substrate according to the present embodiment.

(The Semiconductor Substrate)

First, the structure of the semiconductor substrate according to the present embodiment will be explained with reference to FIG. 1.

The semiconductor substrate according to the present embodiment is characterized mainly by a strained Si/SiGe structure having an isotope composition ratio of ²⁸Si of a silicon crystal layer 14 set high.

As shown in FIG. 1, a 200 nm-thickness silicon germanium crystal layer 12 is epitaxially grown on the silicon crystal substrate 10. The silicon germanium crystal layer 12 has a composition of, e.g., Si_{0.7}Ge_{0.3}.

A 200 nm-thickness silicon crystal layer 14 is epitaxially grown on the silicon germanium crystal layer 12. The ²⁸Si isotope composition ratio of the silicon crystal layer 14 is, e.g., 99.9%. Crystal strains are introduced into the silicon crystal layer 14 because of a lattice constant of the silicon crystal layer 14 different from that of the silicon germanium crystal layer 12. In the present embodiment, since the crystal strains are introduced into the silicon crystal layer 14, it is possible to obtain high carrier mobility.

A plane orientation of the surface of the silicon crystal layer 14 is, e.g., {100}.

It is reported that the usual <110> direction of the channel of a MOSFET is changed to <100>, which increases the driving capacity of the p-channel MOSFET by about 15% (see Reference 16: G. Ottaviani, et al., Phys. Rev. B12, 3318 (1975)).

In order to make a channel direction of a MOSFET <100>, an orientation flat or a notch is set to be <011>+45° or <011>−45°. This permits a MOSFET to have <100> channel direction.

The substrate is aligned to have <100> channel direction in the exposure step, whereby a MOSFET can have <100> channel direction.

A plane orientation of the surface of the silicon crystal layer may be {113}.

It has been confirmed by TDDB (Time Dependent Dielectric Breakdown) that a silicon oxide film formed on a semiconductor wafer a plane orientation of the surface of which is {113} has better insulation than silicon oxide film formed on a semiconductor wafer a plane orientation of the surface of which is {100} (see Reference 17: H-J. Mussig, et al., Proc. 3rd Int'l Symp. of Advanced Sci. and Tech. of Si Mat., The Jpn Soc. Prom. Sci., 2000, p. 374). Reasons for the better insulation of the silicon oxide film formed on a {113} semiconductor wafer are that a stress in the interface between the silicon oxide film and the silicon crystal layer is smaller than that of the silicon oxide film formed on a {100} semiconductor wafer, and that roughness of the {113} surface is about ½ of that of the {100} surface (see Reference 17). Based on this, the plane orientation of the silicon crystal layer 14 is set to be {113}, whereby MOSFETs, etc. of high reliability will be able to be fabricated.

A plane orientation of the silicon crystal layer 14 may be {011}.

A p-channel MOSFET fabricated on a semiconductor wafer the plane orientation of the surface of which is {011} has higher hole mobility in comparison with a p-channel MOSFET fabricated on a semiconductor wafer the plane orientation of the surface of which is {100} (see Reference 18: T. Sato et al., Phys. Rev. B4, 1950 (1971)). However, when an n-channel MOSFET is fabricated on a semiconductor wafer the plane orientation of the surface of which is {011}, the electron mobility is decreased by about 20% in comparison with that of an n-channel MOSFET the plane orientation of the surface of which is {100}.

However, an operational speed of a CMOS circuit is determined by a mobility of holes, whose mobility is lower than electrons. To increase the operational speed of the CMOS circuit it is important to increase the mobility of holes in the p-channel MOSFETs.

As described above, the plane orientation of the silicon crystal layer 14 is set to be {011}, whereby the operational speed of the p-channel MOSFET can be further improved.

As described above, according to the present embodiment, the isotope composition ratio of ²⁸Si of the silicon crystal layer 14 is set to be so high as 99.9%, whereby the thermal conductivity of the silicon crystal layer 14 can be increased. Thus, according to the present embodiment, scattering of the heat in the direction horizontal to the substrate surface can be accelerated. According to the present embodiment, the heat generated in the core part, hot spots, etc. of the microprocessor can be effectively radiated. The semiconductor substrate according to the present embodiment can have heat radiation improved, and can contribute to higher operational speed and higher reliability of high end ultrafast devices.

(The Method for Fabricating the Semiconductor Substrate)

Next, the method for fabricating the semiconductor substrate according to the present embodiment will be explained with reference to FIGS. 2A to 2C. FIGS. 2A to 2C are sectional views of the semiconductor substrate according to the present embodiment in the steps of the method for fabricating the semiconductor substrate, which explained the method.

First, as shown in FIG. 2A, a silicon crystal substrate 10 is prepared.

Then, as shown in FIG. 2B, the 200 nm-thickness silicon germanium crystal layer 12 is epitaxially grown on the silicon crystal substrate 10 by, e.g., CVD (Chemical Vapor Deposition) A composition of the silicon germanium crystal layer 12 is, e.g., Si_{0.7}Ge_{0.3}. As a raw material gas for the Si, monosilane (SiH₄) for example, is used. As a raw material gas for the Ge, germane (GeH₄) is used. These raw material gases are usual raw material gases whose isotope abundance ratios are not specifically controlled. Because usual raw material gases whose isotope abundance ratios are not specified are used, isotope abundance ratios of the Si and the Ge of the silicon germanium crystal layer 12 are the same as those of Si and Ge in nature.

Then, as shown in FIG. 2C, the 200 nm-thickness silicon crystal layer 14 is epitaxially grown on the silicon germanium crystal layer 12 by, e.g., CVD. As a raw material gas for the Si, monosilane (²⁸SiH₄) having, e.g., a 99.9% isotope composition ratio of ²⁸Si is used. Thus, the silicon crystal layer 14 having, e.g., a 99.9% isotope composition ratio of ²⁸Si can be formed. Because of a difference in the lattice constant between the silicon crystal layer 14 and the silicon germanium crystal layer 12, crystal strains are introduced into the silicon crystal layer 14.

When the silicon crystal layer 14 is formed, in order to control a specific resistance of the silicon crystal layer 14, raw material gas, hydrogen (H₂) and raw material gas for boron are used together with the raw material gas for the Si. As the raw material gas for the boron, diborane (B₂H₆), for example, is used. However, to control a specific resistance of the silicon crystal layer 14 is not directly involved in the contents of the present invention and will not be explained below.

Thus, the semiconductor substrate according to the present embodiment is fabricated.

[A Second Embodiment]

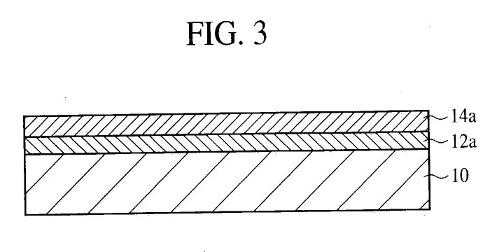

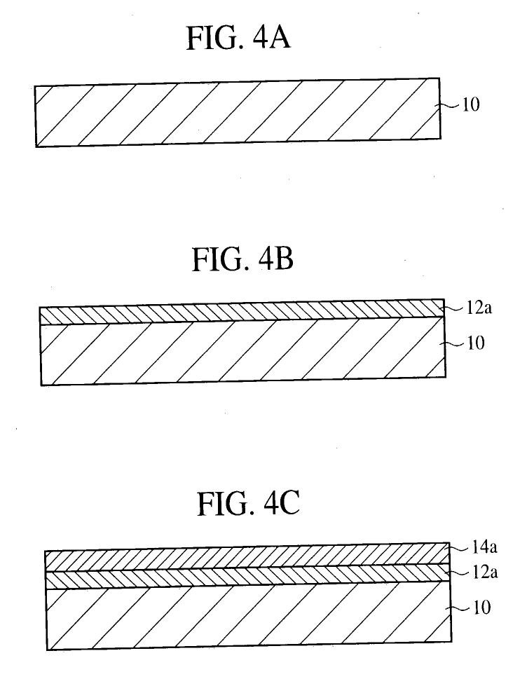

The semiconductor substrate according to a second embodiment of the present invention and the method for fabricating the semiconductor substrate will be explained with reference to FIGS. 3 to 4C. FIG. 3 is a sectional view of the semiconductor substrate according to the present embodiment. The same members of the present embodiment as those of the semiconductor substrate and the method for fabricating the semiconductor substrate shown in FIGS. 1 to 2C are represented by the same reference numbers not to repeat or to simplify their explanation.

(The Semiconductor Substrate)

First, the semiconductor substrate according to the present embodiment will be explained with reference to FIG. 3.

The semiconductor substrate according to the present embodiment is characterized mainly by a strained Si/SiGe structure having ⁷⁰Ge isotope composition ratio of a silicon germanium crystal layer 12a set high.

As shown in FIG. 3, the silicon germanium crystal layer 12a of a 200 nm-thickness is formed on a silicon crystal substrate 10. A composition of the silicon germanium crystal layer 12a is, e.g., Si_{0.7}Ge_{0.3}. An isotope composition ratio of ⁷⁰Ge of the silicon germanium crystal layer 12a is, e.g., 99.9%. The isotope abundance ratio of the Si of the silicon germanium crystal layer 12a is the same as that of Si in nature.

In the present embodiment, the isotope abundance ratio of the Si of the silicon germanium crystal layer 12a is the same as that of Si in nature, but the isotope composition ratio of ²⁸Si of the silicon germanium crystal layer 12a may be set higher. That is, the isotope composition ratios of both ⁷⁰Ge and ²⁸Si of the silicon germanium crystal layer 12a may be set higher.

A 200 nm-thickness silicon crystal layer 14a is epitaxially grown on the silicon germanium crystal layer 12a. Because of a difference in the lattice constant between the silicon crystal layer 14a and the silicon germanium crystal layer 12a, crystal strains are introduced into the silicon crystal layer 14a. The isotope abundance ratio of Si of the silicon crystal layer 14a is the same as that of Si in nature. The plane orientation of the surface of the silicon crystal layer 14a is, e.g., {100}, {113} or {011}.

The semiconductor substrate according to the present embodiment is characterized mainly in that an isotope composition ratio of ⁷⁰Ge of the silicon germanium crystal layer 12a is set as high as 99.9% as described above.

According to the present embodiment, an isotope composition ratio of ⁷⁰Ge of the silicon germanium crystal layer 12a is set high, whereby the thermal conductivity of the silicon germanium crystal layer 12a can be increased. Thus, the semiconductor substrate according to the present embodiment can efficiently radiate heat.

(The Method for Fabricating the Semiconductor Device)

Then, the method for fabricating the semiconductor substrate according to the present embodiment will be explained with reference to FIGS. 4A to 4C. FIGS. 4A to 4C are sectional views of the semiconductor substrate according to the present embodiment in the steps of the method for fabricating the semiconductor substrate, which explain the method.

First, as shown in FIG. 4A, the silicon crystal substrate 10 is prepared.

Then, as shown in FIG. 4B, the 200 nm-thickness silicon germanium crystal layer 12a is epitaxially grown on the silicon crystal substrate 10. A composition of the silicon germanium crystal layer 12a is, e.g., Si_{0.7}Ge_{0.3}. As a raw material gas of the Ge, a raw material gas having, e.g., a ⁷⁰Ge isotope composition ratio of, e.g., 99.9% is used. As a raw material gas of the Si, a usual raw material gas having the isotope abundance ratio of Si specifically not controlled is used. Thus, the silicon germanium crystal layer having a 99.9% isotope composition ratio of ⁷⁰Ge is foremd.

Next, as shown in FIG. 4C, the 20 nm-thickness silicon crystal layer 14a of silicon crystals is epitaxially grown on the silicon germanium crystal layer 12a by, e.g., CVD. As a raw material gas, a usual raw material gas an Si isotope abundance ratio of which is not specifically controlled is used.

Thus, the semiconductor substrate according to the present embodiment is fabricated.

[A Third Embodiment]

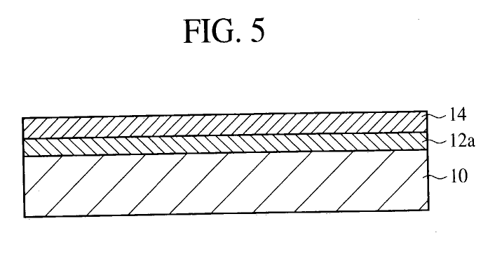

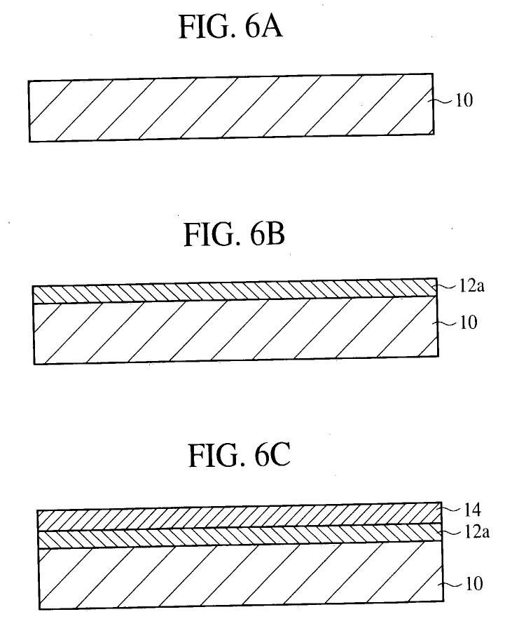

The semiconductor substrate according to a third embodiment of the present invention and the method for fabricating the semiconductor substrate will be explained with reference to FIGS. 5 to 6C. FIG. 5 is a sectional view of the semiconductor substrate according to the present embodiment. The same members of the present embodiment as those of the semiconductor substrate and the method for fabricating the semiconductor substrate according to the first or the second embodiment shown in FIGS. 1 to 4C are represented by the same reference numbers not to repeat or to simplify their explanation

(The Semiconductor Substrate)

The semiconductor substrate according to the present embodiment will be explained with reference to FIG. 5.

The semiconductor substrate according to the present embodiment is characterized mainly by a strained Si/SiGe structure having a ⁷⁰Ge isotope composition ratio of a silicon germanium crystal layer 12a set high and a ²⁸Si isotope composition ratio of a silicon crystal layer 14 set high.

As shown in FIG. 5, the silicon germanium crystal layer 12a of a 200 nm thickness is epitaxially grown on a silicon crystal substrate 10. An isotope composition ratio of ⁷⁰Ge of the silicon germanium crystal layer 12a is set as high as, e.g., 99.9%. The isotope abundance ratio of Si of the silicon germanium crystal layer 12a is the same as that of Si in nature.

In the present embodiment, the isotope abundance ratio of Si of the silicon germanium crystal layer 12a is the same as that of Si in nature, but an isotope composition ratio of ²⁸Si of the silicon germanium crystal layer 12a may be set higher. That is, isotope composition ratios of both ⁷⁰Ge and ²⁸Si of the silicon germanium crystal layer 12a may be set higher.

The silicon crystal layer 14 of a 20 nm thickness is grown on the silicon germanium crystal layer 12a. Crystal strains are introduced into the silicon crystal layer 14. An isotope composition ratio of ²⁸Si of the silicon crystal layer 14 is set as high as, e.g., 99.9%. A plane orientation of the surface of the silicon crystal layer 14 is, e.g., {100}, {113} or {011}.

The semiconductor substrate according to the present embodiment is characterized mainly in that, as described above, an isotope composition ratio of ⁷⁰Ge of the silicon germanium crystal layer 12a is set high, and an isotope composition ratio of ²⁸Si of the silicon crystal layer 14 is set high.

According to the present embodiment, an isotope composition ratio of ⁷⁰Ge of the silicon germanium crystal layer 12a is set high, and an isotope composition ratio of ²⁸Si of the silicon crystal layer 14 is set high, whereby the thermal conductivity of both the silicon germanium crystal layer 12a and the silicon layer 14 can be increased. Thus, the semiconductor substrate according to the present embodiment can more effectively radiate the heat.

(The Method for Fabricating the Semiconductor Substrate)

Next, the method for fabricating the semiconductor substrate according to the present embodiment will be explained with reference to FIGS. 6A to 6C. FIGS. 6A to 6C are sectional views of the semiconductor substrate according to the present embodiment in the steps of the method for fabricating the semiconductor substrate, which explain the method.

First, as shown in FIG. 6A, the silicon crystal substrate 10 is prepared.

Next, as shown in FIG. 6B, the 200 nm-thickness silicon germanium crystal layer 12a is epitaxially grown on the silicon crystal substrate 10 by, e.g., CVD. The composition of the silicon germanium crystal layer 12a is, e.g., Si_{0.7}Ge_{0.3}. As a raw material gas of the Ge, a raw material gas a ⁷⁰Ge isotope composition ratio of which is, e.g., 99.9% is used. As a raw material gas of the Si, a raw material gas having the isotope abundance ratio of the Si not specifically controlled is used. Thus, the silicon germanium crystal layer 12a a ⁷⁰Ge isotope composition ratio of which is, e.g., 99.9% is formed.

Then, the 20 nm-thickness silicon crystal layer 14 is epitaxially grown on the silicon germanium crystal layer 12a by, e.g., CVD. As a raw material of the Si, a raw material gas an ²⁸Si isotope composition ratio of which is 99.9% is used.

Thus, the semiconductor substrate according to the present embodiment is fabricated.

[A Fourth Embodiment]

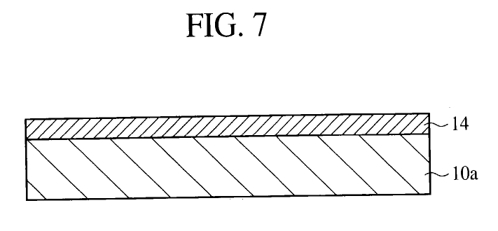

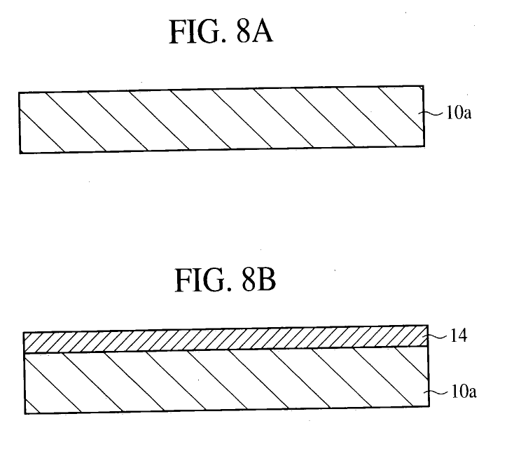

The semiconductor substrate according to a fourth embodiment of the present invention and the method for fabricating the semiconductor substrate will be explained with reference to FIGS. 7 to 8B. FIG. 7 is a sectional view of the semiconductor substrate according to the present embodiment. The same members of the present embodiment as those of the semiconductor substrate according to the first to the third embodiments and the method for fabricating the semiconductor substrate shown in FIGS. 1 to 6C are represented by the same reference numbers not to repeat or to simplify their explanation.

(The Semiconductor Substrate)

The semiconductor substrate according to the present embodiment is characterized mainly in that a silicon germanium crystal substrate is used as a base substrate, and a silicon crystal layer a ²⁸Si isotope composition ratio of which is high is formed on the silicon germanium crystal substrate.

As shown in FIG. 7, in the present embodiment, the silicon germanium crystal substrate 10a is used as the base substrate. The composition of the silicon germanium crystal substrate 10a is, e.g., Si_{0.7}Ge_{0.3}.

The silicon crystal layer 14 of a 20 nm-thickness is formed on the silicon germanium crystal substrate 10. Crystal strains are introduced into the silicon crystal layer 14. A ²⁸Si isotope composition ratio of the silicon crystal layer 14 is, e.g., 99.9%. The plane orientation of the surface of the silicon crystal layer 14 is, e.g., {100}, {113} or {011}.

As described above, the semiconductor substrate according to the present embodiment is characterized mainly in that the silicon germanium crystal substrate 10a is used as a base substrate, and the silicon crystal layer 14 a ²⁸Si isotope composition ratio of which is high is formed on the silicon germanium crystal substrate 10a.

According to the present embodiment, the silicon germanium crystal substrate 10a is used as the base substrate, which permits the strained silicon crystal layer 14 to be formed directly on the base substrate. Thus, the semiconductor device according to the present embodiment can effectively radiate the heat and can be fabricated by simpler steps.

(The Method for Fabricating the Semiconductor Substrate)

Next, the method for fabricating the semiconductor substrate according to the present embodiment will be explained with reference to FIGS. 8A and 8B. FIGS. 8A and 8B are sectional views of the semiconductor substrate according to the present embodiment in the steps of the method for fabricating the semiconductor substrate, which explain the method.

First, as shown in FIG. 8A, the silicon germanium crystal substrate 10a is prepared. A. composition of the silicon germanium crystal substrate 10a is, e.g., Si_{0.7}Ge_{0.3}.

Then, the silicon crystal layer 14 of a 20 nm-thickness is epitaxially grown on the silicon germanium crystal substrate 10a by, e.g., CVD. As a raw material gas of the Si, monosilane (²⁸SiH₄) a ²⁸Si isotope composition ratio of which is, e.g., 99.9% is used. Thus, the silicon crystal layer 14 a ²⁸Si isotope composition ratio of which is, e.g., 99.9% is fabricated. A lattice constant difference between the silicon crystal layer 14 and the silicon germanium crystal substrate 10a introduce crystal strains into the silicon crystal layer 14.

Thus, the semiconductor substrate according to the present embodiment is fabricated.

[A Fifth Embodiment]

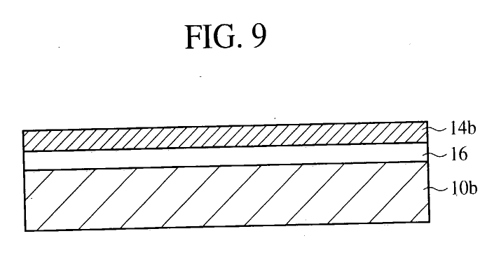

The semiconductor substrate according to a fifth embodiment of the present invention and the method for fabricating the semiconductor substrate will be explained with reference to FIGS. 9 to 11B. FIG. 9 is a sectional view of the semiconductor substrate according to the present embodiment. The same members of the present embodiment as those of the semiconductor substrate according to the first to the fourth embodiments and the method for fabricating the semiconductor substrate shown in FIGS. 1 to 8B are represented by the same reference numbers not to repeat or to simplify their explanation.

(The Semiconductor Substrate)

The semiconductor substrate according to the present embodiment will be explained with reference to FIG. 9.

The semiconductor substrate according to the present embodiment is firstly characterized mainly by an SOI substrate fabricated by bonding, which has a ²⁸Si isotope composition ratio of a silicon crystal layer 14b set high.

As shown in FIG. 9, in the present embodiment, a base substrate 10b of silicon crystals and the silicon crystal layer 14b are bonded with an insulation film 16 formed therebetween. The insulation film 16 is formed of SiO₂ of a 200 nm-thickness. A ²⁸Si isotope composition ratio of the silicon crystal layer 14b is, e.g., 99.9%. The base substrate 10b is a usual silicon crystal substrate having the isotope abundance ratio not specifically controlled. In the semiconductor substrate according to the present embodiment, which is the SOI substrate fabricated by bonding, an oxygen concentration profile in the interface between the base substrate 10b and the insulation film 16, and an oxygen concentration profile in the interface between the insulation film and the silicon crystal layer 14b are steeper than an oxygen concentration profile in the SOI substrate fabricated by SIMOX (Separation by IMplantation of OXygen).

The plane orientation of the surface of the silicon crystal layer 14b is, e.g., {100}.

The specification of Japanese Patent Laid-Open Publication No. Hei9-246505/1997 describes an SOI substrate bonded with the <011> axis of the silicon crystal layer and the <011> axis of the base substrate forming an angle of 10-45° By using such SOI substrate, even when a MOSFET is fabricated by the usual exposure, the channel direction of the transistors can be along <100>. Accordingly, by using the bonding described in the specification of Japanese Patent Laid-Open Publication No. Hei9-246505/1997 in fabricating the semiconductor substrate according to the present embodiment, even when a MOSFET is fabricated by the usual exposure, the channel direction can be along <100>.

The plane orientation of the silicon crystal layer may be {113} or {011}.

As described above, the semiconductor substrate according to the present embodiment is firstly characterized mainly in that a ²⁸Si isotope composition ratio of the silicon crystal layer 14b is set so high as 99.9%.

According to the present embodiment, a ²⁸Si isotope composition ratio of the silicon crystal layer 14b is set so high as 99.9%, whereby the thermal conductivity of the silicon crystal layer 14b can be increased. Thus, the semiconductor substrate according to the present embodiment can effectively radiate Joule's heat generated in transistors (not shown), etc. fabricated on the silicon crystal layer 14b, etc.

The semiconductor substrate according to the present embodiment is secondly characterized mainly by an SOI substrate fabricated by bonding as described above.

Reference 11 describes an SOI substrate including a silicon crystal layer a ²⁸Si isotope composition ratio of which is set to be above 92.2%. However, the SOI substrate described in Reference 11 will not be able to have good heat radiation for the following reason.

In Reference 11, the buried oxide film is formed by SIMOX. In forming a buried oxide film by SIMOX, oxygen ions (¹⁶O⁺) are implanted at the surface of a silicon crystal substrate at a 180 keV acceleration energy and a 4×10¹⁷ cm⁻² dose, for example, and then thermal processing is performed in an atmosphere of a mixed gas of argon and oxygen, at 1350° C. and for several hours, for example, to thereby form the buried oxide film (Reference 19: S. Nakashima. et al., J. Electrochem. Soc. 143, 244 (1996)).

When the buried oxide film is thus formed by SIMOX, a large number of interstitial Si atoms are implanted into the silicon crystal layer both at the interface between the silicon oxide film formed on the surface of the silicon crystal layer, and the silicon crystal layer, and at the interface between the buried oxide film and the silicon crystal layer. Because the thermal processing temperature, 1350° C., for forming the buried oxide film is very near 1400° C., which is the dissolution temperature of silicon crystals, an enormous number of interstitial Si atoms are implanted into the silicon crystal layer. The interstitial Si atoms implanted into the silicon crystal layer are trapped and reside in the silicon crystal layer, which is sandwiched between the buried oxide film and the silicon oxide film.

In the high end ultrafast device using the SOI substrate, which uses full depleted MOSFETs, the thickness of the silicon crystal layer has a very small thickness of, e.g., below 50 nm. In the SOI substrate, a thickness of the silicon crystal layer of which is set small for higher operational speed of the MOSFETs, a concentration of interstitial Si atoms in the silicon crystal layer is very high. When heat processing of about 1000° C. is performed in fabricating the MOSFETs, the interstitial Si atoms are deposited to resultantly form stacking faults.

It is reported that, in the SOI substrate including the buried oxide film by SIMOX, dislocations caused by implantation of oxygen ions are present in the silicon crystal layer in a density of several hundred dislocations/cm² (see Reference 20: S. Nakashima, et al., Electron, Lett. 26, 1647 (1990)).

Thermal conduction is propagation of lattice vibrations thermally excited in waves. When an enormous number of crystal defects and dislocations in the silicon crystal layer, progressive waves of lattice vibrations are scattered. Accordingly, the SOI substrate described in Reference 11 cannot provide good heat radiation.

In contrast to this, according to the present embodiment, the SOI substrate is fabricated by bonding, whereby the generation of stacking faults and dislocations in the silicon crystal layer 14b can be prevented. Thus, the semiconductor substrate according to the present embodiment can have higher thermal conductivity of the silicon crystal layer 14b and can effectively radiate the heat.

(The Method for Fabricating the Semiconductor Substrate)

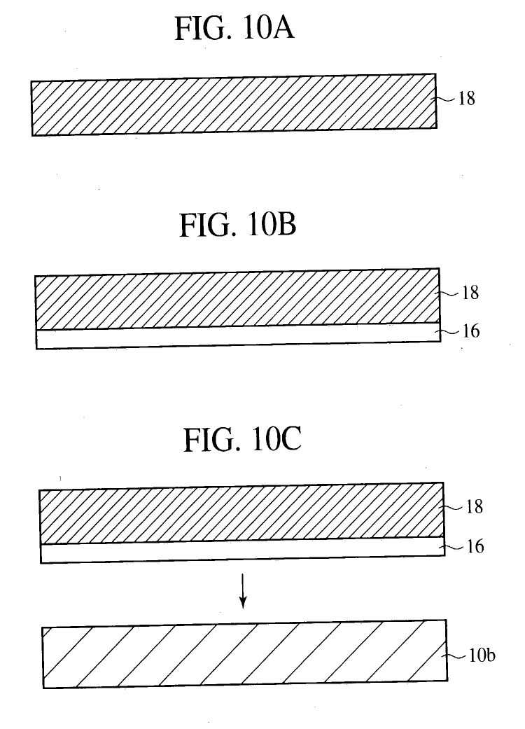

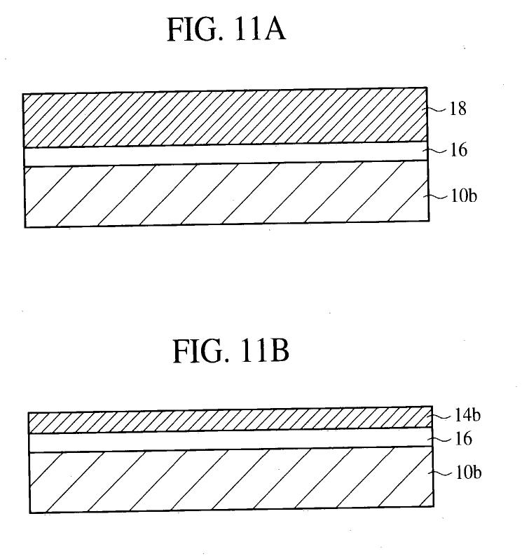

Next, the semiconductor substrate according to the present embodiment and the method for fabricating the semiconductor substrate will be explained with reference to FIGS. 10A to 11B. FIGS. 10A to 11B are sectional views of the semiconductor substrate according to the present embodiment in the steps of the method for fabricating the semiconductor substrate, which explain the method.

As shown in FIG. 10A, the silicon crystal substrate 18 a ²⁸Si isotope concentration of which is, e.g., 99.9% is prepared. The silicon crystal substrate 18 is to be thinned in a later step to be the silicon crystal layer 14b of the SOI substrate.

Next, as shown in FIG. 10B, the insulation film 16 of SiO₂ is formed on the surface of the silicon crystal substrate 14b by thermal oxidation or CVD.

As shown in FIG. 10C, the base substrate 10b of silicon crystal is prepared.

Next, as shown in FIG. 11A, the silicon crystal substrate 18 and the base substrate 10b are bonded to each other with the insulation film 16 formed therebetween.

Then, as shown in FIG. 11B, the silicon crystal substrate 18 is thinned by mechanical processing or chemical etching. Thus, the silicon crystal layer 14b is formed of the thinned silicon crystal substrate 18.

Thus, the semiconductor substrate according to the present embodiment is fabricated.

(Modification)

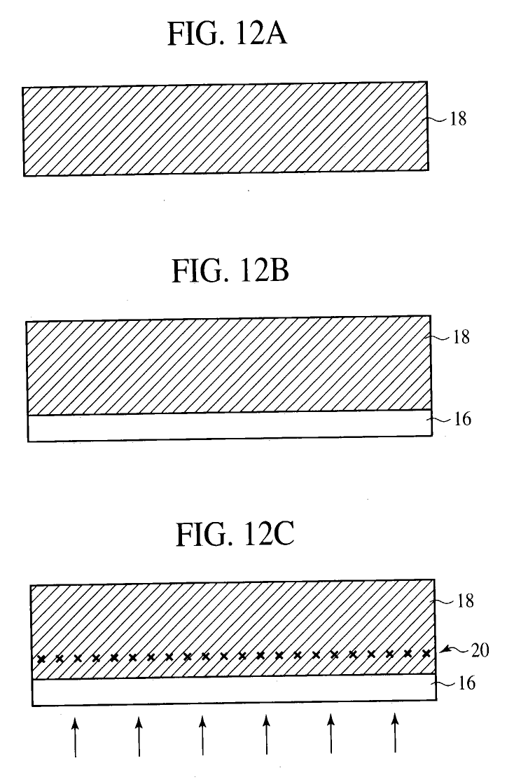

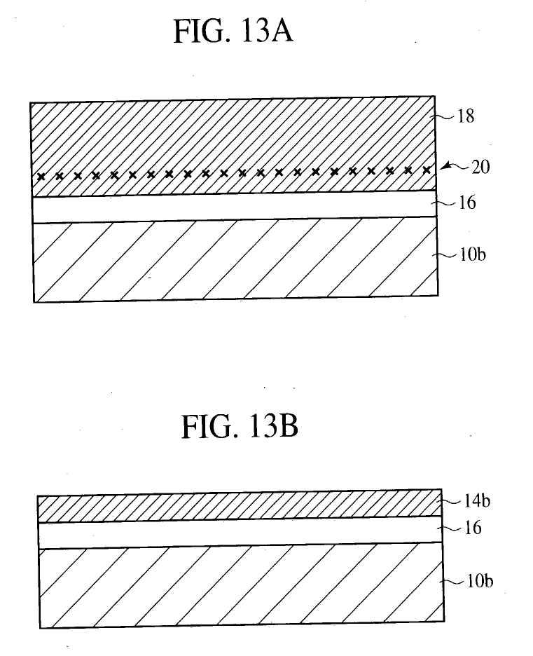

Next, a modification of the method for fabricating the semiconductor substrate according to the present embodiment will be explained with reference to FIGS. 12A to 13B. FIGS. 12A to 13B are sectional views of the semiconductor substrate in the steps of method for fabricating the semiconductor substrate according to the present modification, which explain the method.

The modification of the method for fabricating the semiconductor substrate according to the present embodiment is characterized mainly in that the silicon crystal substrate 18 is thinned by cleavage to thereby form the silicon crystal layer 14b of the silicon crystal substrate 18.

First, the steps of the present modification up to the step of forming the insulation film 16 on the surface of the silicon crystal substrate 18 including the insulation film forming step are the same as those of the method for fabricating the semiconductor substrate described above with reference to FIGS. 10A and 10B, and their explanation will not be repeated (see FIGS. 12A and 12B).

Then, as shown in FIG. 12C, hydrogen ions are implanted into the silicon crystal substrate 18 through the insulation film 16. In the drawing, the region 20 with the hydrogen ions implanted in is indicated by crosses (×).

Next, as shown in FIG. 13A, the silicon crystal substrate 18 and the base substrate 10b are bonded to each other with the insulation film 16 therebetween.

Then, as shown in FIG. 13B, the silicon crystal substrate 18 is separated along the region 20 with the hydrogen ions implanted in. The silicon crystal substrate 18 is thus thinned by cleavage to form the silicon crystal layer 14b of the silicon crystal substrate 18. In a case that the surface of the silicon crystal layer 14b has to be further planarized, the surface of the silicon crystal layer 14b is polished by CMP (Chemical Mechanical Polishing) (not shown).

As described above, the silicon crystal layer 14b may be formed of the silicon crystal substrate 18by thinning the silicon crystal substrate 18 by cleavage.

[A Sixth Embodiment]

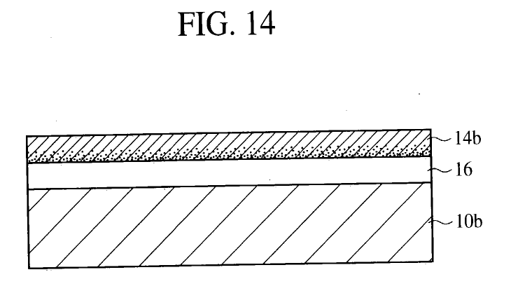

The semiconductor substrate according to a sixth embodiment of the present invention and the method for fabricating the semiconductor substrate will be explained with reference to FIGS. 14 to 16C. FIG. 14 is a sectional view of the semiconductor substrate according to the present embodiment. The same members of the present embodiment as those of the semiconductor substrate and the method for fabricating the semiconductor substrate shown in FIGS. 1 to 13B are represented by the same reference numbers not to repeat or to simplify their explanation.

(The Semiconductor Substrate)

First, the semiconductor substrate according to the present embodiment will be explained with reference to FIG. 14.

The semiconductor substrate according to the present embodiment is characterized mainly by an SOI substrate fabricated by bonding with carbon (C) atoms implanted in a region of a silicon crystal layer 14b, which is nearer to the interface between an insulation film 16 and the silicon crystal layer 14b.

As shown in FIG. 14, carbon atoms are implanted in the region of the silicon crystal layer 14b, which is nearer to the interface between the silicon crystal layer 14b and the insulation film 16. In the drawing, the region with the carbon atoms implanted is indicated by dots. In the drawing, denser dots indicate more heavily implanted carbon atoms. A carbon concentration in the region nearer to the interface between the silicon crystal layer 14b and the insulation film 16 is, e.g., about 5×10²⁰ cm⁻³ at the most heavily implanted part.

In the present embodiment, carbon atoms are implanted in a region of the silicon crystal layer 14b, which is nearer to the interface between the silicon crystal layer 14b and the insulation film 16 so as to mitigate a tensile strain exerted to the silicon crystal layer 14b in the region thereof nearer to the interface between the insulation film 16 and the silicon crystal layer 14b.

It is known that generally strains are present in the interface between silicon crystals and silicon oxide film. It is considered that strains are generated also in the interface between the silicon crystal layer and the buried insulation film of the SOI substrate. Because of the thermal expansion coefficient of the silicon crystal layer, which is higher than that of the silicon oxide film, in a case that the silicon oxide film is formed directly on the silicon crystals, tensile strains are generated in the silicon crystal layer nearer to the interface between the silicon crystal layer and the silicon oxide film, and compression strains are generated in the silicon oxide film nearer to the interface of the silicon crystal layer and the silicon oxide film. A tensile stress generated in the silicon crystal layer nearer to the interface between the silicon crystal layer and the silicon oxide film is about 1×10⁹-4×10⁹ dyn/cm², and a tensile strain generated in the silicon crystal layer nearer to the interface between the silicon crystal layer and the silicon oxide film is about 1×10⁻³-4×10⁻³ (see Reference 21: R. J. Jaccodine, et al., J. Appl. Phys. 37, 2429 (1966); Reference 22: G. Lucovsky et al., The Physics and Chemistry of SiO₂ and the SiO₂ Interface, edited by C. R. Helms, et al., Plenum Press, NY, 1988, p. 139).

The stress thus generated in the interface between the silicon crystal layer and the silicon oxide film will be similarly generated even in a case that an isotope composition ratio of any one of the isotopes of silicon crystal layer is set high. The strain generated in the region nearer to the interface between the silicon crystal layer and the insulation film scatters lattice vibration waves propagating in the silicon crystal layer, and will be a cause for lowering the thermal conductivity.

Then, in the present embodiment, carbon atoms are implanted in the silicon crystal layer 14b nearer to the interface between the silicon crystal layer 14b and the insulation film 16. Because of the covalent radius of Si atom, which is smaller than that of carbon atom, carbon atoms are implanted to thereby contract the crystal lattices expanded in the silicon crystal layer 14b, and the tensile strain can be mitigated (principle of strain compensation).

Carbon atoms, which are electrically neutral in the silicon crystal 14b, are implanted in the silicon crystal layer 14b without affecting electric characteristics of MOSFETs, etc. to be fabricated on the silicon crystal layer 14b.

According to the present embodiment, crystal strains of the silicon crystal layer 14b nearer to the interface between the silicon crystal layer 14b and the insulation film 16 can be mitigated, whereby the thermal conductivity of the silicon crystal layer 14b can be higher, and the semiconductor substrate can more effectively radiate the heat.

In the present embodiment, a concentration of carbon atoms implanted in the silicon crystal layer 14b nearer to the interface between the insulation film 16 and the silicon crystal layer 14b is 5×10²⁰ cm⁻³ but is not essentially limited to 5×10²⁰ cm⁻³.

A concentration of carbon atoms to be implanted may be set suitably so as to mitigate the tensile strain exerted to the silicon crystal layer 14b nearer to the interface between the insulation film 16 and the silicon crystal layer 14b. A suitable concentration of carbon atoms to be implanted in the silicon crystal layer 14b nearer to the interface between the insulation film 16 and the silicon crystal layer 14b can be given as follows.

A strain ε generated in a crystal lattice by the implantation of an impurity can be given by the following formula (see Reference 23: H. J. Herzog, et al., J. Electrochem. Soc., 131, 2969 (1984)).

ε=αᵢ×N_{C} (i=L, V) (2)

α_{L}=[1−(R_{C}/R_{Si})]×D⁻¹ (3)

α_{V}=[1−(R_{C}/R_{Si})³]×(3D)⁻¹ (4)

wherein αᵢ represents a lattice contraction coefficient; N_{C}; a concentration of implanted carbon atoms; R_{Si} represents a covalent radius of Si; R_{C} represents a covalent radius of carbon; D represents an atom density of an Si crystal lattice; α_{L} represents a lattice contraction coefficiency of a linear model; and α_{V} represents a lattice contraction coefficiency of a volume model.

When an Si covalent radius, a carbon covlanet radius, and an Si crystal atom density are substituted respectively 0.117 nm (see Reference 23), 0.077 nm (see Reference 24: Bunichi Tamamushi et al., Rikagakujiten, 3rd supplemented edition, 1983, Iwanami Shoten, p. 324) and 5×10²² cm⁻² in Formula 3 and Formula 4, α_{L} and α_{V} are as follows.

α_{L}=6.84×10⁻²⁴ (5)

α_{V}=4.77×10⁻²⁴ (6)

Then, when Formulae 2, 5 and 6 are used, and ε=1×10⁻³, a carbon atom concentration N_{C} for mitigating a tensile strain of the silicon crystal layer 14b is

N_{C}=1.46×10²⁰−2.10×10²⁰ cm⁻³.

When Formulae 2, 5 and 6 are used, and ε=4×10⁻³, a carbon atom concentration N_{C} for mitigating a tensile strain of the silicon crystal layer 14b is

N_{C}=5.85×10²⁰−8.39×10²⁰ cm⁻³.

Here, a difference between the values of N_{C} for the one and the same strain is made by computing the values by using both the linear model and volume model.

Based on the above, in order to make the mitigation of a tensile strain of the silicon crystal layer nearer to the interface between the insulation film 16 and the silicon crystal layer 14b practically effective, it is suitable to set a concentration of carbon atoms to be implanted to be 1×10²⁰-1×10²¹ cm⁻³.

The concentration of carbon atoms to be implanted in a region of the silicon crystal layer 14b nearer to the interface between the insulation film 16 and the silicon crystal layer 14b is not limited to 1×10²⁰-1×10²¹ cm⁻³; when a carbon concentration is below 1×10²⁰ cm⁻³ or when a carbon concentration is above 1×10²¹ cm⁻³, a tensile strain in the region of the silicon crystal layer 14b nearer to the interface between the insulation film 16 and the silicon crystal layer 14b can be mitigated to some extent. That is, as long as carbon atoms are implanted in a region of the silicon crystal layer 14b nearer to the interface between the insulation film 16 and the silicon crystal layer 14b, a tensile strain in the region of the silicon crystal layer 14b nearer to the interface between the insulation film 16 and the silicon crystal layer 14b can be mitigated to some extent.

As carbon atoms to be implanted, ¹²C may be used, or ¹³C maybe used. However, the isotope abundance ratio of ¹²C in nature is so high as 98.89% (see Reference 25: Bunichi Tamamushi et al., Rikagakujiten, 3rd supplemented edition, 1983, Iwanami Shoten, p. 1560). That is, the ¹²C isotope composition ratio is so high without specifically controlling the abundance ratio of an isotope of carbon to be implanted. Accordingly, even by implanting the usual carbon atoms without controlling an isotope abundance ratio, the same effect as that produced by controlling an isotope composition ratio of ¹²C will be produced.

As described above, according to the present embodiment, the SOI substrate fabricated by bonding has carbon atoms implanted in the region of the silicon crystal layer 14b nearer to the interface between the insulation film 16 and the silicon crystal layer 14b, whereby the tensile strain of the silicon crystal layer 14b can be mitigated. According to the present embodiment, the tensile strain of the silicon crystal layer 14b can be mitigated, whereby the thermal conductivity of the silicon crystal layer 14b can be higher, and the semiconductor substrate can have good heat radiation.

In many of high end ultrafast devices using the SOI substrate, full depletion type-MOSFETs are fabricated In the full depletion type-MOSFETs, in operation, the depletion layer reaches the interface between the silicon crystal layer 14b and the insulation film 16. Accordingly, the electric characteristics of the MOSFETs are susceptible to strains of the interface between the silicon crystal layer 14b and the insulation film 16. According to the present embodiment, as described above, the strain in the interface between the silicon crystal layer 14b and the insulation film 16 can be mitigated, and accordingly the electric characteristics of the MOSFETs can be also better.

As described above, according to the present embodiment, the thermal conductivity of the silicon crystal layer 14b can be increased, and the electric characteristics of MOSFETs, etc. to be fabricated on the silicon crystal layer 14b can be also better.

In the present embodiment, the SOI substrate including the silicon crystal layer 14b having a ²⁸Si isotope composition ratio set high has carbon atoms implanted in the region of the silicon crystal layer 14b nearer to the interface between the silicon crystal layer 14b and the insulation film 16. The usual SOI substrate including the silicon crystal layer 14b having an isotope abundance ratio of Si not specifically controlled has carbon atoms implanted in the region of the silicon crystal layer 14b nearer to the interface between the silicon crystal layer 14b and the insulation film 16, whereby the electric characteristics of MOSFETs, etc. to be fabricated on the silicon crystal layer 14b can be also better.

(The Method for Fabricating the Semiconductor Substrate)

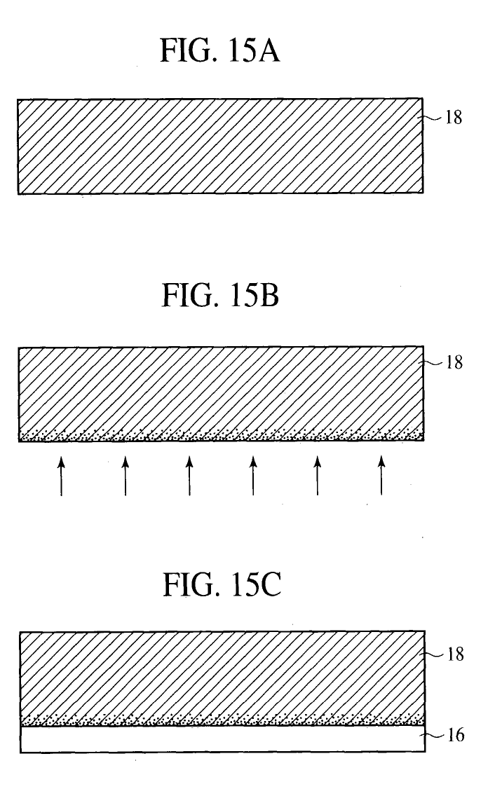

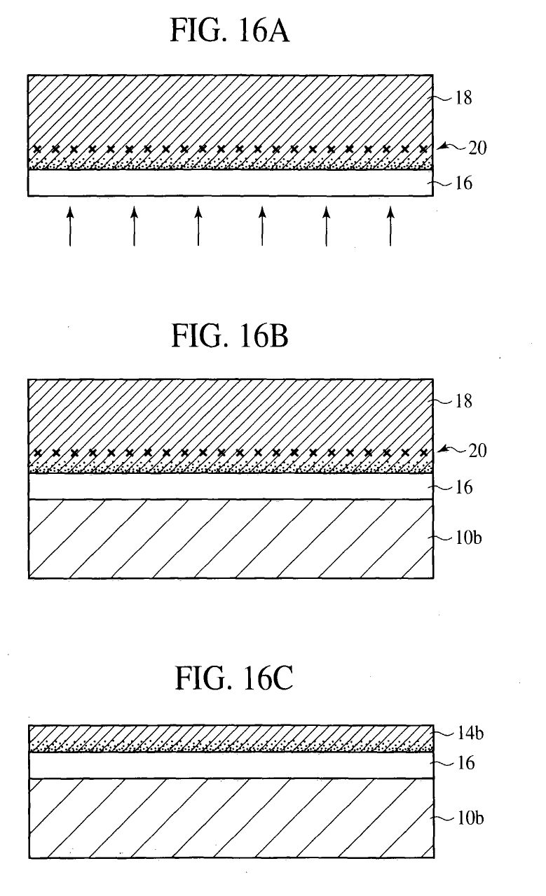

Next, the method for fabricating the semiconductor substrate according to the present embodiment will be explained with reference to FIGS. 15A to 16C. FIGS. 15A to 16C are sectional views of the semiconductor substrate according to the present embodiment in the steps of the method for fabricating the substrate, which explain the method.

First, as shown in FIG. 15A, the silicon crystal substrate 18 having an isotope concentration of ²⁸Si is, e.g., 99.9% is prepared.

Then, as shown in FIG. 15B, carbon atoms are implanted by ion implantation in a region of the silicon crystal substrate 18 which is nearer to the surface thereof. At this time, carbon atoms are implanted so that a concentration of the carbon atoms in the silicon crystal substrate 18 nearer to the surface is, e.g., 5×10²⁰ cm⁻³. Carbon atoms are implanted so that a concentration of the carbon atoms lowers gradually from the surface of the silicon crystal substrate 18 to the inside of the silicon crystal substrate 18. In the drawings, the carbon atoms are indicated by dots. In the drawings, higher densities of the dots indicate higher cabon concentrations.

Next, as shown in FIG. 15C, the insulation film 16 of SiO₂ is formed on the surface of the silicon crystal substrate 18 by thermal oxidation or CVD.

Next, as shown in FIG. 16A, hydrogen ions are implanted in the silicon crystal substrate 18 on the side of the insulation film 16. In the drawing, the region 20 where the hydrogen ions have been implanted is indicated by crosses.

Then, as shown in FIG. 16B, the silicon crystal substrate 18 and the base substrate 10b are bonded to each other with the insulation film 16 formed therebetween.

Next, as shown in FIG. 16C, the silicon crystal substrate 18 is separated by cleavage in the region 20 with the hydrogen ions implanted in, whereby the silicon crystal layer 14 is formed of the thinned silicon crystal substrate 18.

Thus, the semiconductor substrate according to the present embodiment is fabricated.

(Modification 1)

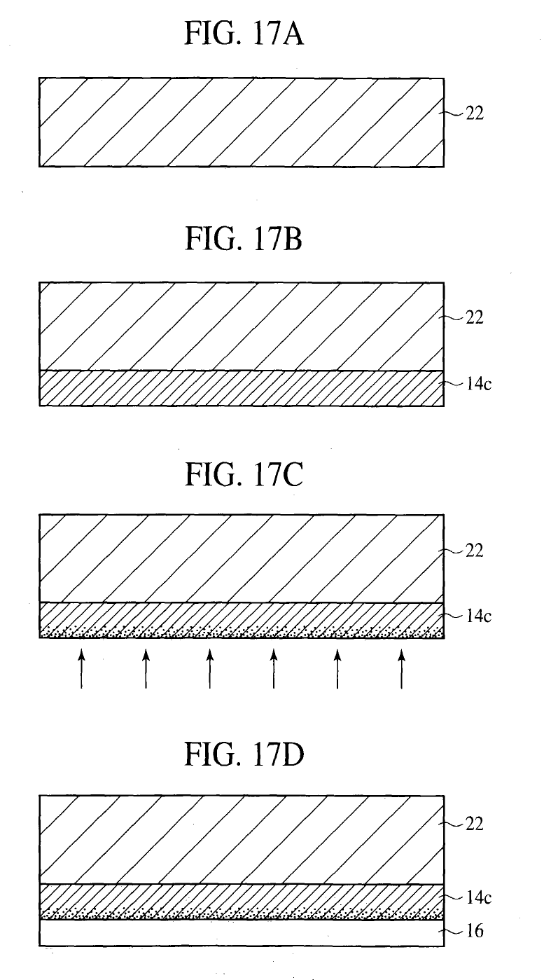

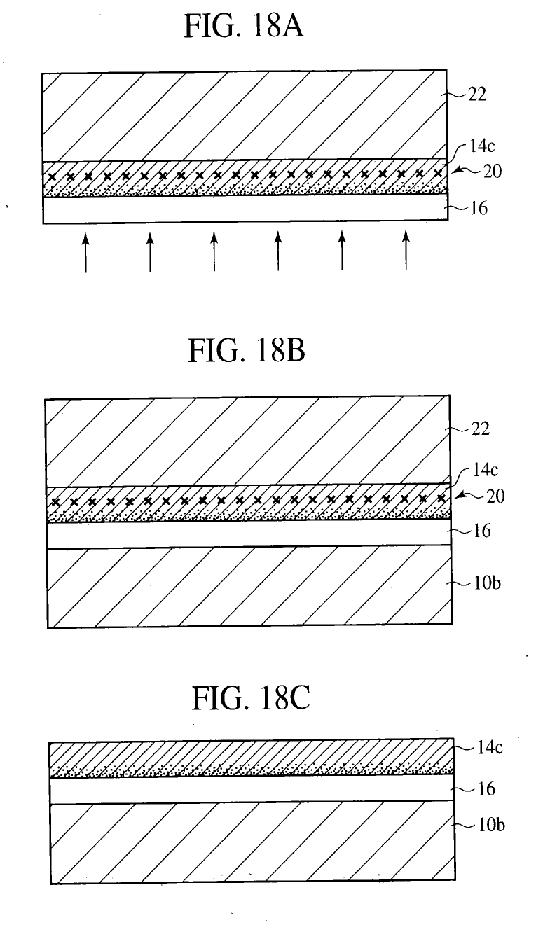

Next, Modification 1 of the method for fabricating the semiconductor substrate according to the present embodiment will be explained with reference to FIGS. 17A to 18C. FIGS. 17A to 18C are sectional views of the semiconductor substrate in the steps of method for fabricating the semiconductor substrate according to the present modification, which explain the method.

The semiconductor substrate fabricating method according to the present modification is characterized mainly in that the SOI substrate is fabricated by forming a silicon crystal layer 14c having a ²⁸Si isotope concentration of, e.g., 99.9% on a usual silicon crystal substrate 22 having the isotope abundance ratio not specifically controlled and bonding the silicon crystal layer 14c and the base substrate 10b with the insulation film 16 formed therebetween.

First, as shown in FIG. 17A, a usual silicon crystal substrate 22 having the isotope abundance ratio not controlled is prepared.

Next, as shown in FIG. 17B, the silicon crystal layer 14c having a 99.9% ²⁸Si isotope composition ratio is epitaxially grown by, e.g., CVD. The thickness of the silicon crystal layer 14c is, e.g., 500 nm. As a raw material gas, a raw material gas of a 99.9% ²⁸Si isotope composition ratio is used. Thus, the silicon crystal layer 14c of, e.g., a 99.9% ²⁸Si isotope composition ratio is formed.

Next, as shown in FIG. 17C, carbon atoms are implanted in the region of the silicon crystal layer 14c nearer to the surface thereof by ion implantation. At this time, carbon atoms are implanted so that a carbon concentration of in the region of the silicon crystal layer 14c nearer to the surface thereof is, e.g., 5×10²⁰ cm⁻³. The carbon atoms are implanted so that the carbon concentration is decreased gradually from the surface of the silicon crystal layer 14c to the inside of the silicon crystal layer 14c.

Then, as shown in FIG. 17d, the insulation film 16 of SiO₂ is formed on the surface of the silicon crystal layer 14c by, e.g., thermal oxidation.

Next, as shown in FIG. 18A, hydrogen ions are implanted into the silicon crystal layer 14c through the insulation film 16. At this time, the hydrogen ions are implanted into a region which is deeper than the region with carbon atoms implanted in. In the drawing, the region 20 with the hydrogen ions implanted in is indicated by crosses.

Then, as shown in FIG. 18B, the silicon crystal substrate 22 and the base substrate 10b are bonded to each other through the silicon crystal layer 14c and the insulation film 16.

Next, as shown in FIG. 18C, the silicon crystal layer 14c is separated by cleavage in the region 20 with the hydrogen ions implanted in.

Thus, the semiconductor substrate is fabricated by the present modification.

As described above, the SOI substrate may be fabricated by forming the silicon crystal layer 14c of, e.g., a 99.9% ²⁸Si isotope concentration on the usual silicon crystal substrate 22 with the isotope abundance ratio not controlled, and bonding the silicon crystal layer 14c to the base substrate 10b through the insulation film 16.

(Modification 2)

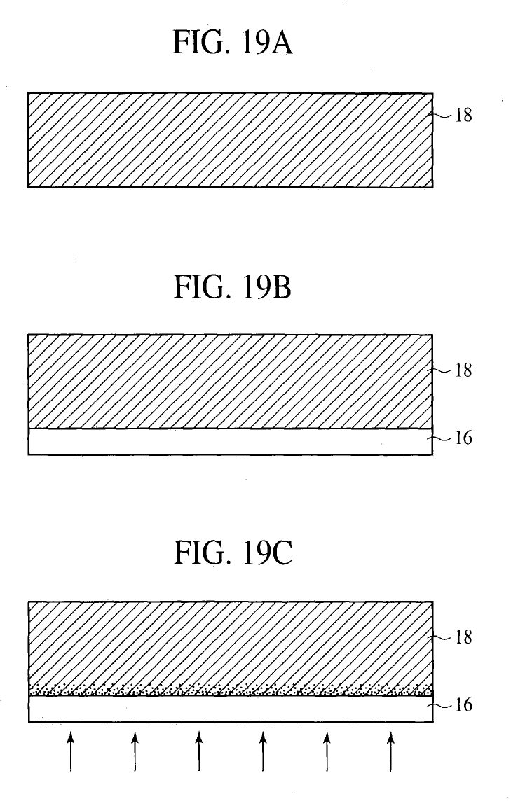

Next, Modification 2 of the method for fabricating the semiconductor substrate according to the present embodiment will be explained with reference to FIGS. 19A to 19C. FIGS. 19A to 19C are sectional views of the semiconductor substrate in the steps of method for fabricating the semiconductor substrate according to the present modification, which explain the method.

The semiconductor substrate fabricating method according to the present modification is characterized mainly in that the insulation film 16 is formed on the silicon crystal substrate 18 of a e.g., 99.9% ²⁸Si isotope concentration, and then carbon atoms are implanted in a region of the silicon crystal layer 18 nearer to the interface between the silicon crystal substrate 18 and the insulation film 16.

The steps up to the step of forming the insulation film 16 of SiO₂ on the surface of, e.g., a 99.9% ²⁸Si isotope concentration including the insulation film 16 forming step are the same as those of the semiconductor substrate fabricating method described above with reference to FIGS. 10A and 10B, and their explanation will not be repeated (see FIGS. 19A and 19B).

Next, as shown in FIG. 19C, carbon atoms are implanted in a region of the silicon crystal substrate 18 nearer to the interface between the silicon crystal substrate 18 and the insulation film 16 through the insulation film 16. A carbon concentration is, e.g., 5×10²⁰ cm⁻³. Carbon atoms are implanted so that the carbon concentration is decreased gradually from the interface between the silicon crystal substrate 18 and the insulation film 16 to the inside of the silicon crystal substrate 18.

The following steps are the same as those of the semiconductor substrate fabricating method described above with reference to FIGS. 16A to 16C, and their explanation will not be repeated.

Thus, the semiconductor substrate is fabricated by the present modification.

As described above, it is possible that the insulation film 16 is formed on the silicon crystal substrate 18 of, e.g. a 99.9% ²⁸Si isotope concentration, and then carbon atoms are implanted in the silicon crystal substrate 18 through the insulation film 16.

(Modification 3)

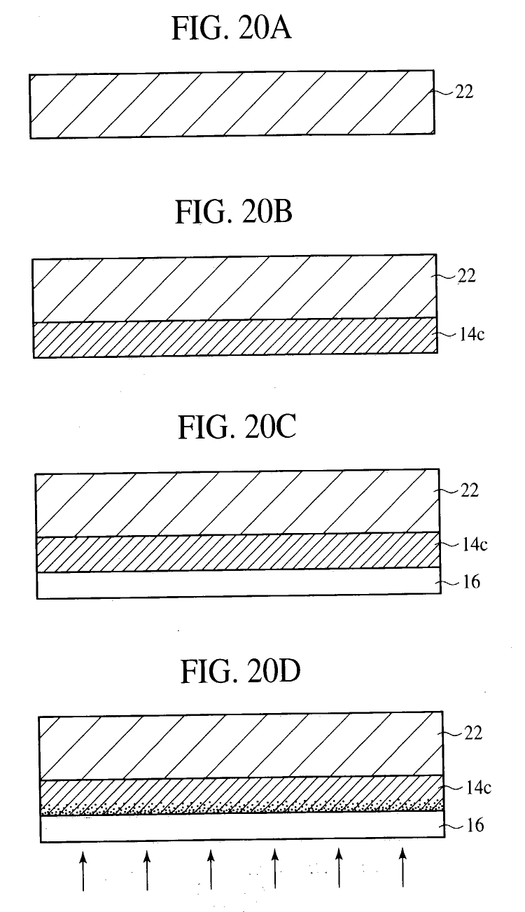

Next, Modification 3 of the method for fabricating the semiconductor substrate according to the present embodiment will be explained with reference to FIGS. 20A to 20D. FIGS. 20A to 20D are sectional views of the semiconductor substrate in the steps of method for fabricating the semiconductor substrate according to the present modification, which explain the method.

The semiconductor substrate fabricating method according to the present modification is characterized mainly in that the silicon crystal layer 14c of, e.g., a 99.9% ²⁸Si isotope concentration is formed on the silicon crystal substrate 22 having the Si isotope concentration not controlled, and after the insulation film 16 is formed on the silicon crystal layer 14c, carbon atoms are implanted in the silicon crystal layer 14c through the insulation film 16.

The steps up to the step of epitaxially growing the silicon crystal layer of a 99.9% ²⁸Si isotopoe composition ratio on the usual silicon crystal substrate 22 having the isotope abundance ratio not specifically controlled including the silicon crystal layer epitaxially growing step are the same as those of the semiconductor substrate fabricating method shown in FIGS. 17A and 17B, and their explanation will not be repeated (see FIGS. 20A and 20B).

Next, as shown in FIG. 20C, the insulation film 16 of SiO₂ is formed on the surface of the silicon crystal layer 14c by, e.g., thermal oxidation.

Next, as shown in FIG. 20D, carbon atoms are implanted by ion implantation into a region of the silicon crystal layer 14c nearer to the interface between the silicon crystal layer 14c and the insulation film 16 through the insulation film 16. At this time, carbon atoms are implanted so that a carbon concentration in the region of the silicon crystal layer nearer to the interface between the silicon crystal layer 14c and the insulation film 16 is, e.g., 5×10²⁰ cm⁻³. The carbon atoms are implanted so that the carbon concentration decreases gradually from the interface between the silicon crystal layer 14c and the insulation film 16 to the inside of the silicon crystal layer 14c.

The following steps are the same as those of the semiconductor substrate fabricating method described above with reference to FIGS. 18A to 18C, and their explanation will not be repeated.

Thus, the semiconductor substrate according to the present modification is fabricated.

As described above, it is possible that the silicon crystal layer 14c of a 99.9% ²⁸Si isotope concentration is formed on the silicon crystal substrate 22 having concentration of the Si isotopes not controlled, and after the insulation film 16 has been formed on the silicon crystal layer 14c, carbon atoms are implanted in the silicon crystal layer 14c through the insulation film 16.

(Modification 4)

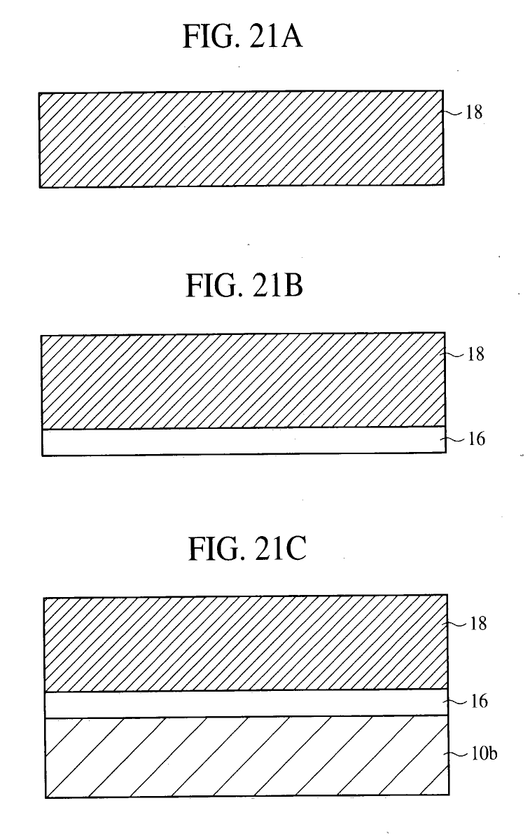

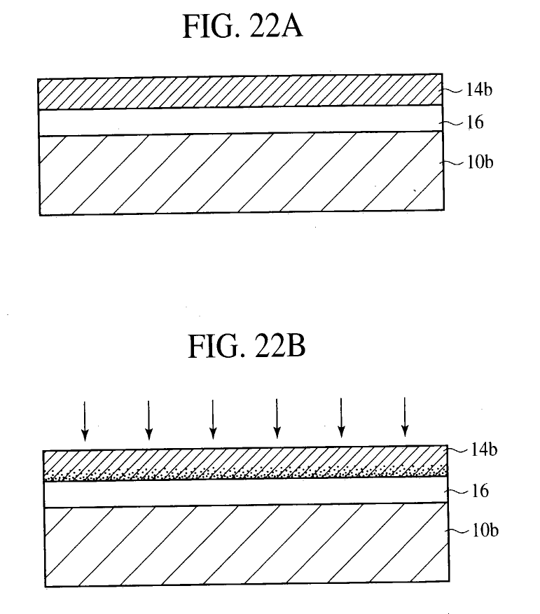

Next, Modification 4 of the method for fabricating the semiconductor substrate according to the present embodiment will be explained with reference to FIGS. 21A to 22B. FIGS. 21A to 22B are sectional views of the semiconductor substrate in the steps of method for fabricating the semiconductor substrate according to the present modification, which explain the method.

The semiconductor substrate fabricating method according to the present modification is characterized mainly in that the silicon crystal substrate 18 is thinned, and the silicon crystal layer 14b is formed of the thinned silicon crystal substrate 18, and then carbon atoms are implanted in a region of the silicon crystal layer 14b nearer to the interface between the silicon crystal layer 14b and the insulation film 16.

First, the steps up to the step of forming the insulation film 16 of SiO₂ on the surface of the silicon crystal substrate 18 of, e.g., a 99.9% ²⁸Si isotope concentration including the insulation film forming step are the same as those of the semiconductor substrate fabricating method described above with reference to FIGS. 10A and 10B, and their explanation will not be repeated (see FIGS. 21A and 21B).

Next, as shown in FIG. 21C, the silicon crystal substrate 18 and the base substrate 10b are bonded to each other with the insulation film 16 formed therebetween.

Then, as shown in FIG. 22A, the silicon crystal substrate 18 is thinned by mechanical processing or chemical etching. Thus, the silicon crystal layer 14b is formed of the thinned silicon crystal substrate 18.

Next, as shown in FIG. 22B, carbon atoms are implanted in the region of the silicon crystal layer 14b nearer to the interface between the silicon crystal layer 14b and the insulation film 16 by ion implantation. The carbon concentration is, e.g., 5×10²⁰ cm⁻³. The carbon atoms are implanted so that the carbon concentration decreases gradually from the interface between the silicon crystal layer 14b and the insulation film 16 to the inside of the silicon crystal layer 14b.

Thus, the semiconductor substrate according to the present modification is fabricated.

As described above, it is possible that the silicon crystal substrate 18 is thinned, and after the silicon crystal layer 14b has been formed of the thinned silicon crystal substrate 18, carbon atoms are implanted into the region of the silicon crystal layer 14b nearer to the interface between the silicon crystal layer 14b and the insulation film 16.

(Modification 5)

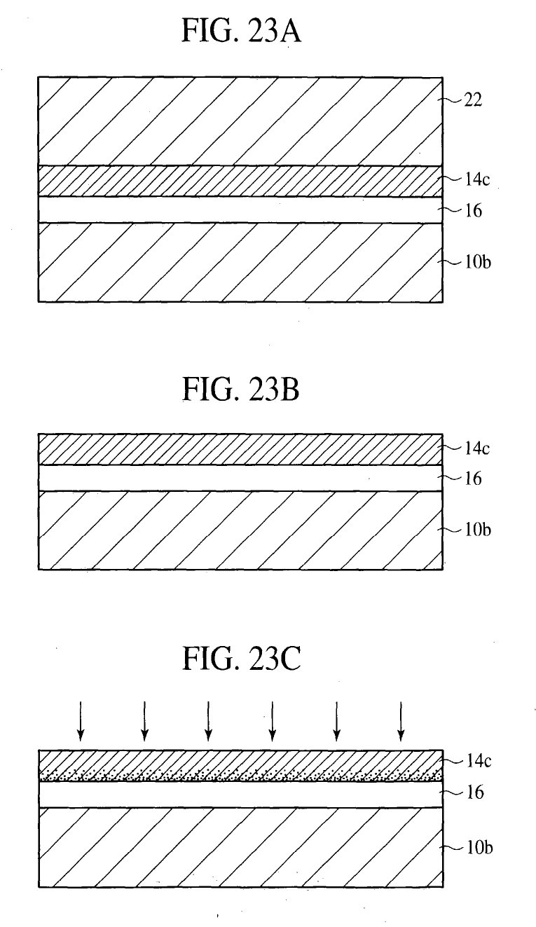

Next, Modification 5 of the method for fabricating the semiconductor substrate according to the present embodiment will be explained with reference to FIGS. 23A to 23C. FIGS. 23A to 23C are sectional views of the semiconductor substrate in the steps of method for fabricating the semiconductor substrate according to the present modification, which explain the method.

The semiconductor substrate fabricating method according to the present modification is characterized mainly in that the silicon crystal layer 14c of a high ²⁸Si isotope composition ratio on the silicon crystal substrate 22 of abundance ratio of the Si isotopes not controlled, and after the silicon crystal layer 14c is bonded to the base substrate 10b with the insulation film 16 formed therebetween, carbon atoms are implanted into the region of the silicon crystal layer 14c nearer to the interface between the silicon crystal layer 14c and the insulation film 16.

The steps up to the step of forming the insulation film 16 of SiO₂ on the surface of the silicon crystal layer 14c including the insulation film forming step are the same as those of the method for fabricating the semiconductor substrate described above with reference to FIG. 20A to FIG. 20C, and their explanation will not be repeated.

Then, as shown in FIG. 23A, the silicon crystal substrate 22 and the base substrate 10b are bonded to each other with the insulation film 16 and the silicon crystal layer 14c formed therebetween.

Next, as shown in FIG. 23B, the silicon crystal substrate 22 is removed by mechanical processing or chemical etching.

Then, as shown in FIG. 23C, carbon atoms are implanted into the region of the silicon crystal layer 14c nearer to the interface between the silicon crystal layer 14c and the insulation film 16 by ion implantation. The carbon concentration is, e.g., 5×10²⁰ cm⁻³. The carbon atoms are implanted so that the carbon concentration is decreased gradually from the interface between the silicon crystal layer 14c and the insulation film 16 to the surface of the silicon crystal layer 14c.

Thus, the semiconductor substrate according to the present modification is fabricated.

As described above, it is possible that the silicon crystal layer 14c of a high ²⁸Si isotope composition ratio is formed on the silicon crystal substrate 22 with abundance ratio of the Si isotopes not controlled, and after the silicon crystal layer 14c and the base substrate 10b are bonded to each other with the insulation film 16 formed therebetween, carbon atoms are implanted into the region of the silicon crystal layer 14b nearer to the interface between the silicon crystal layer 14b and the insulation film 16.

[A Seventh Embodiment]

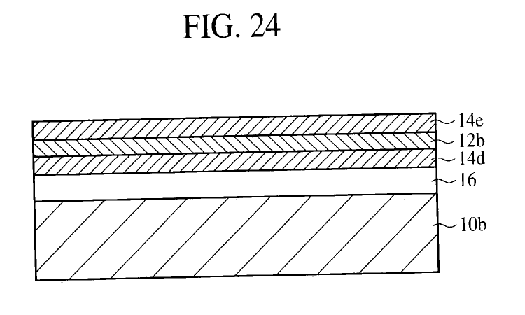

The semiconductor substrate according to a seventh embodiment of the present invention and the method for fabricating the semiconductor substrate will be explained with reference to FIGS. 24 to 26C. FIG. 24 is a sectional view of the semiconductor substrate according to the present embodiment. The same members of the present embodiment as those of the semiconductor substrate according to the first to the sixth embodiments and the method for fabricating the semiconductor substrate shown in FIGS. 1 to 23c are represented by the same reference numbers not to repeat or to simplify their explanation.

(The Semiconductor Substrate)

First, the semiconductor substrate according to the present embodiment will be explained with reference to FIG. 24.

The semiconductor substrate according to the present embodiment is characterized mainly by a strained Si/SiGeOI structure having an isotope composition ratio of ²⁸Si of a silicon crystal layer 14e set high.

As shown in FIG. 24, a silicon crystal layer 14d of, e.g., a 30 nm-thickness is formed on a silicon crystal substrate 10b with an insulation film 16 of SiO₂ formed therebetween. A Si isotope abundance ratio of the silicon crystal layer 14d is the same as that of Si in nature.

A silicon germanium crystal layer 12b is formed on the silicon crystal layer 14d. A thickness of the silicon germanium crystal layer 12b is, e.g., 200 nm. A Ge composition of the silicon germanium crystal layer 12b is set to increase gradually from the lower surface to the upper surface. That is, the composition of the silicon germanium crystal layer 12b is a graded composition. A concentration of the Ge near the lower surface of the silicon germanium crystal layer 12b is, e.g., 0%. A concentration of the Ge near the upper surface of the silicon germanium crystal layer 12b is, e.g., 30%. The Ge composition of the silicon germanium crystal layer 12b is set to increase gradually from the lower surface to the upper surface so that the silicon germanium crystal layer 12b can be epitaxially grown on the silicon crystal layer 14d, and a composition of the Ge in the upper surface of the silicon germanium crystal layer 12b can be set higher. The isotope abundance ratio of the Si and the Ge of the silicon germanium crystal layer 12b is substantially equal to that of Si and Ge in nature.

The silicon crystal layer 14e of, e.g., a 20 nm-thickness is epitaxially grown on the silicon germanium crystal layer 12b. An ²⁸Si isotope composition ratio of the silicon crystal layer 14e is, e.g., 99.9%. Because of different lattice constants between the upper surface of the silicon germanium crystal layer 12b and the silicon crystal layer 14e, the silicon crystal layer 14e is crystal strained.

A plane orientation of the silicon crystal layer 14e is, e.g., {100} {113} or {011}.

The semiconductor substrate according to the present embodiment is characterized mainly, as described above, by the strained Si/SiGeOI structure having a ²⁸Si isotope composition ratio of the silicon crystal layer 14e set high.

The semiconductor substrate of such strained Si/SiGeOI structure can effectively radiate the heat because of the ²⁸Si isotope composition ratio of the silicon crystal layer 14e, which is set high.

(The Method for Fabricating the Semiconductor Substrate)

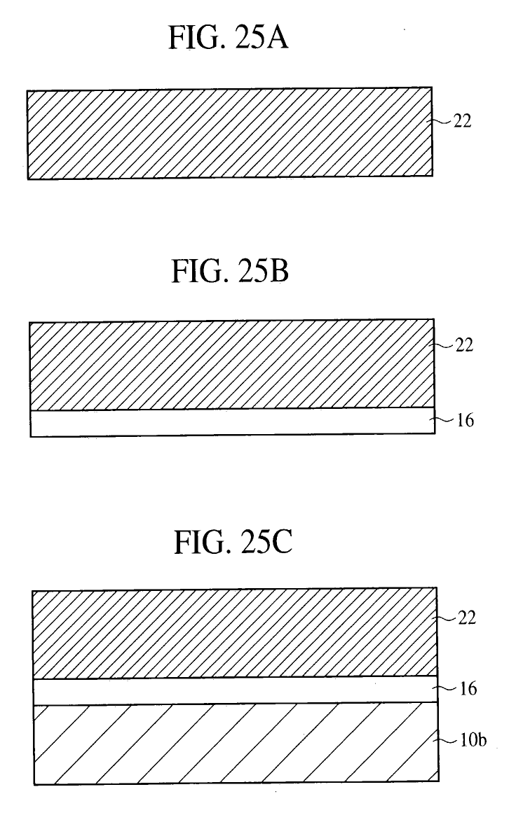

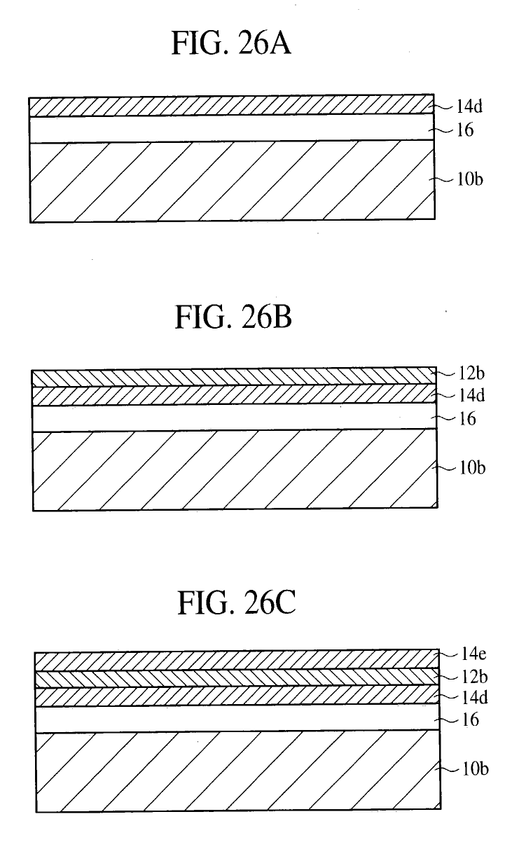

Next, the method for fabricating the semiconductor substrate according to the present embodiment will be explained with reference to FIGS. 25A to 26C. FIGS. 25A to 26C are sectional views of the semiconductor substrate according to the present embodiment in the steps of the method for fabricating the semiconductor substrate, which explain the method.

First, as shown in FIG. 25A, the usual silicon crystal substrate 22 of silicon crystals having the isotope abundance ratio not specifically controlled is prepared. The silicon crystal substrate 22 is to be thinned in a later step to form the silicon crystal layer 14d.

Next, as shown in FIG. 25B, the insulation film 16 of SiO₂ is formed on the surface of the silicon crystal substrate 22 by thermal oxidation or CVD.

As shown in FIG. 25C, the base substrate 10b of usual silicon crystals having the isotope abundance ratio not specifically controlled is prepared.

Next, the silicon crystal substrate 22 and the base substrate 10b are bonded to each other with the insulation film 16 therebetween.

Next, as shown in FIG. 26A, the silicon crystal substrate 22 is thinned by mechanical processing or chemical etching. Thus, the silicon crystal layer 14d is formed of the thinned silicon crystal substrate 22.

Next, as shown in FIG. 26B, the silicon germanium crystal layer 12b is epitaxially grown by, e.g., CVD. As a raw material gas, a raw material gas having the isotope abundance ratio of Si and Ge not specifically controlled is used. A thickness of the silicon germanium crystal layer 12b is, e.g., 200 nm. A composition of the Ge of the silicon germanium crystal layer 12b is set so as to increase gradually from the lower surface to the upper surface. A Ge concentration near the lower surface of the silicon germanium crystal layer 12b is, e.g., 0%, and a Ge concentration near the upper surface of the silicon germanium crystal layer 12b is, e.g., 30%.

Next, as shown in FIG. 26C, the silicon crystal layer 14e of, e.g., a 20 nm-thickness is epitaxially grown on the silicon germanium crystal layer 12b by, e.g., CVD. As a raw material gas, a raw material gas of a ²⁸Si isotope composition ratio of, e.g., 99.9% is used, whereby the silicon crystal layer 14e of a ²⁸Si isotope composition ratio of, e.g., 99.9% is formed. Because of different lattice constants between the surface of the silicon germanium crystal layer 12b and the silicon crystal layer 14e, crystal strains are introduced into the silicon crystal layer 14e.

Thus, the semiconductor substrate according to the present embodiment can be fabricated.

[An Eighth Embodiment]

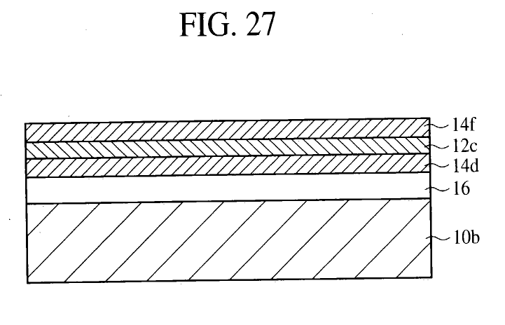

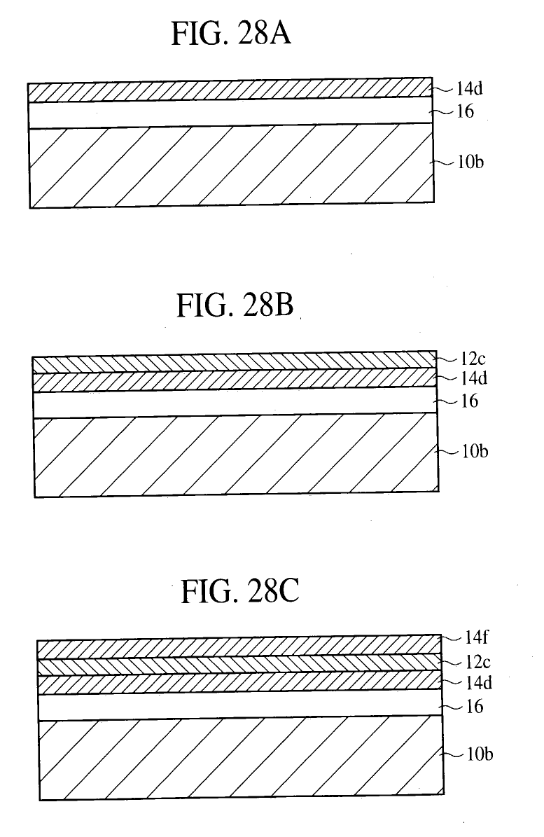

The semiconductor substrate according to an eighth embodiment of the present invention and the method for fabricating the semiconductor substrate will be explained with reference to FIGS. 27 to 28C. FIG. 27 is a sectional view of the semiconductor substrate according to the present embodiment. The same members of the present embodiment as those of the semiconductor substrate according to the first to the seventh embodiments and the method for fabricating the semiconductor substrate shown in FIGS. 1 to 26C are represented by the same reference numbers not to repeat or to simplify their explanation.

(The Semiconductor Substrate)

First, the semiconductor substrate according to the present embodiment will be explained with reference to FIG. 27.

The semiconductor substrate according to the present embodiment is characterized mainly by a strained Si/SiGeOI structure having a ⁷⁰Ge isotope composition ratio of a silicon germanium crystal layer 12c set high.

As shown in FIG. 27, a silicon crystal layer 14d is formed on a base substrate 10b with an insulation film 16 formed therebetween.

A silicon germanium crystal layer 12c is formed on the silicon crystal layer 14d. A ⁷⁰Ge isotope composition ratio of the silicon germanium crystal layer 12c is, e.g., 99.9%. An Si isotope abundance ratio of the silicon germanium crystal layer 12c is the same as that of Si in nature. A Ge composition of the silicon germanium crystal layer 12c is set to increase gradually from the lower surface to the upper surface. A Ge concentration near the lower surface of the silicon germanium crystal layer 12c is, e.g., 0%, and a Ge concentration near the upper surface of the silicon germanium crystal layer 12c is, e.g., 30%.

A silicon crystal layer 14f of, e.g., a 20 nm-thickness is formed on the silicon germanium crystal layer 12c. Crystal strains are introduced into the silicon crystal layer 14f. A Si isotope abundance ratio of the silicon crystal layer 14f is the same as that of the isotope abundance ratio of Si in nature.

As described above, the semiconductor substrate of the strained Si/SiGeOI structure has the ⁷⁰Ge isotope composition ratio of the silicon germanium crystal layer 12c set high, whereby the semiconductor substrate can effectively radiate the heat.

(The Method for Fabricating the Semiconductor Substrate)

Next, the method for fabricating the semiconductor substrate according to the present embodiment will be explained with reference to FIGS. 28A to 28C. FIGS. 28A to 28C are sectional views of the semiconductor substrate according to the present embodiment in the steps of the method for fabricating the semiconductor substrate, which explain the method.

The steps up to the step of thinning the silicon crystal substrate 22 to form the silicon crystal layer 14d of the thinned silicon crystal substrate 22 including the silicon crystal layer forming step are the same as those of the method for fabricating the semiconductor substrate shown in FIGS. 25A to 26A, and their explanation will not be repeated (see FIG. 28A).

Next, as shown in FIG. 28B, the silicon germanium crystal layer 12c is epitaxially grown by, e.g., CVD. As a raw material of the Ge, a raw material gas of a ⁷⁰Ge isotope concentration of, e.g., 99.9% is used. As a raw material gas of the Si, a usual raw material gas having the isotope abundance ratio not specifically controlled is used. A thickness of the silicon germanium crystal layer 12c is, e.g., 200 nm. A Ge composition of the silicon germanium crystal layer 12c is set to increase gradually from the lower surface to the upper surface. A Ge concentration near the lower surface is, e.g., 0%, and a Ge concentration near the upper surface of the silicon germanium crystal layer 12c is, e.g., 30%.

Next, as shown in FIG. 28C, the silicon crystal layer 14f of, e.g., a 20 nm-thickness is epitaxially grown on the silicon germanium crystal layer 12c by, e.g., CVD. As a raw material gas, a usual raw material gas having the isotope abundance ratio not specifically controlled is used.

Thus, the semiconductor substrate according to the present embodiment is fabricated.

[A Ninth Embodiment]

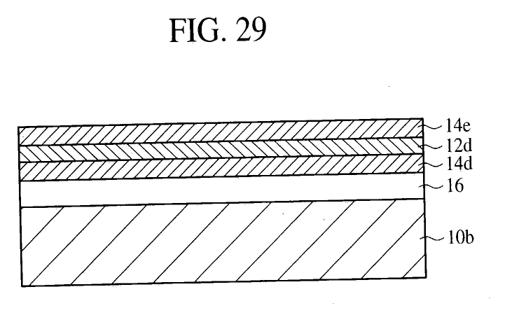

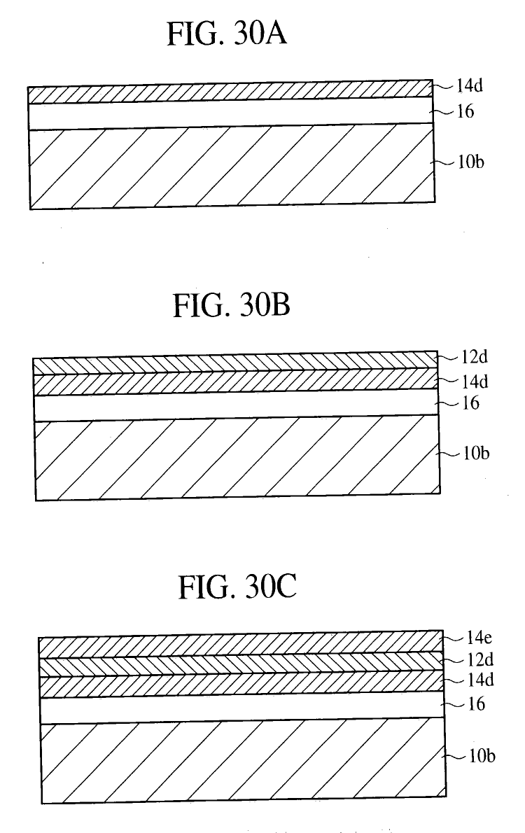

The semiconductor substrate according to a ninth embodiment of the present invention and the method for fabricating the semiconductor substrate will be explained with reference to FIGS. 29 to 30C. FIG. 29 is a sectional view of the semiconductor substrate according to the present embodiment. The same members of the present embodiment as those of the semiconductor substrate according to the first to the eighth embodiments and the method for fabricating the semiconductor substrate shown in FIGS. 1 to 28C are represented by the same reference numbers not to repeat or to simplify their explanation.

(The Semiconductor Substrate)

First, the semiconductor substrate according to the present embodiment will be explained with reference to FIG. 29.

The semiconductor substrate according to the present embodiment is characterized mainly by a strained Si/SiGeOI structure having isotope composition ratios of both ²⁸Si and ⁷⁰Ge of a silicon germanium crystal layer 12d set high, and a ²⁸Si isotope composition ratio of a silicon crystal layer 14e set high.

As shown in FIG. 29, the silicon crystal layer 14d is formed on a base substrate 10b with an insulation film 16 therebetween. An isotope abundance ratio of the silicon crystal layer 14d is the same as that of Si in nature.

The silicon germanium crystal layer 12d is epitaxially grown on the silicon crystal layer 14d. A ²⁸Si isotope abundance ratio of the silicon germanium crystal layer 12d is set to be, e.g., 99.9%. A ⁷⁰Ge isotope composition ratio of the silicon germanium crystal layer 12d is set to be, e.g., 99.9%.

The silicon crystal layer 14e is epitaxially grown on the silicon germanium crystal layer 12d. A ²⁸Si isotope composition ratio of the silicon crystal layer 14e is set to be, e.g., 99.9%.

The semiconductor substrate according to the present embodiment is characterized in that, as described above, isotope composition ratios of ²⁸Si and ⁷⁰Ge of the silicon germanium crystal layer 12d are set high, and a ²⁸Si isotope composition ratio of the silicon crystal layer 14e is set high.

According to the present embodiment, an isotope composition ratios of ²⁸Si and ⁷⁰Ge of the silicon germanium crystal layer 12d are set high, and a ²⁸Si isotope composition ratio of the silicon crystal layer 14e is set high, whereby thermal conductivities of both the silicon germanium crystal layer 12d and the silicon crystal layer 14e can be high. Thus, the semiconductor substrate according to the present embodiment can have the strained Si/SiGeOI structure which can effectively radiate the heat.

(The Method for Fabricating the Semiconductor Substrate)

Next, the method for fabricating the semiconductor substrate according to the present embodiment will be explained with reference to FIGS. 30A to 30C. FIGS. 30A to 30C are sectional views of the semiconductor substrate according to the present embodiment in the steps of the method for fabricating the semiconductor substrate, which explain the method.

First, the steps up to the step of thinning the silicon crystal substrate 22 by mechanical processing or chemical processing to form the silicon crystal substrate 22 of the thinned silicon crystal substrate 22 including the silicon crystal layer forming step are the same as those of the semiconductor substrate fabricating method shown in FIGS. 25A to 26A, and their explanation will not be repeated (see FIG. 30A).

Then, as shown in FIG. 30B, the silicon germanium crystal layer 12d is epitaxially grown by, e.g., CVD. As a raw material gas of the Ge, a raw material gas having a ⁷⁰Ge isotope concentration of, e.g., 99.9% is used. As a raw material gas of the Si, a raw material gas having a ²⁸Si isotope composition ratio of, e.g., 99.9% is used. A thickness of the silicon germanium crystal layer 12d is, e.g., 200 nm. A composition of the Ge of the silicon germanium crystal layer 12d is set to increase gradually from the lower surface to the upper surface. A Ge concentration near the lower surface of the silicon germanium crystal layer 12d is, e.g., 0%, and a Ge concentration near the upper surface of the silicon germanium crystal layer 12c is, e.g., 30%.

Then, as shown in FIG. 30C, the silicon crystal layer 14e of, e.g., a 20 nm-thickness is epitaxially grown on the silicon germanium crystal layer 12c by, e.g., CVD. As a raw material gas, a raw material gas having a ²⁸Si isotope composition ratio of, e.g., 99.9% is used.

Thus, the semiconductor substrate according to the present embodiment is fabricated.

[A Tenth Embodiment]

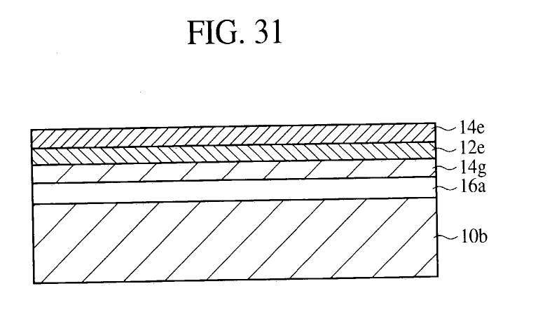

The semiconductor substrate according to a tenth embodiment of the present invention and the method for fabricating the semiconductor substrate will be explained with reference to FIGS. 31 to 33C. FIG. 31 is a sectional view of the semiconductor substrate according to the present embodiment. The same members of the present embodiment as those of the semiconductor substrate according to the first to the ninth embodiments and the method for fabricating the substrate shown in FIGS. 1 to 30C are represented by the same reference numbers not to repeat or to simplify their explanation.

(The semiconductor Substrate)

First, the semiconductor substrate according to the present embodiment will be explained with reference to FIG. 31.

The semiconductor substrate according to the present embodiment is characterized mainly by a strained Si/SiGeOI structure including an insulation film 16a formed by SIMOX (Separation by IMplantation OXygen).

As shown in FIG. 31, the insulation film 16a of SiO₂ is buried in the base substrate 10b of usual silicon crystals having the isotope abundance ratio not controlled. The insulation film 16a is buried in a region which is, e.g., 150 nm deep from the surface of the base substrate 10b. The insulation film 16a is formed by SIMOX. That is, the insulation film 16a is formed by implanting oxygen ions into the base substrate 10b and thermally processing the base substrate 10b. Accordingly, the concentration distribution of the oxygen near the interface between the insulation film 16a and the base substrate 10b is smoother than that of the semiconductor substrate fabricated by the bonding described above.

A silicon crystal layer 14g is formed on the insulation film 16a.

A silicon germanium crystal layer 12e of, e.g., a 200 nm-thickness is formed on the silicon crystal layer 14g. A ²⁸Si isotope composition ratio of the silicon germanium crystal layer 12e is, e.g., 99.9%. An isotope abundance ratio of the Ge of the silicon germanium crystal layer 12e is the same as that of Ge in nature. A Ge composition of the silicon germanium crystal layer 12e is set to increase gradually from the lower surface to the upper surface. A concentration of the Ge near the lower surface of the silicon germanium crystal layer 12e is, e.g., 0%, and a concentration of the Ge near the upper surface of the silicon germanium crystal layer 12e is, e.g., 30%.

The silicon crystal layer 14e of, e.g., a 20 nm-thickness is epitaxially grown on the silicon germanium crystal layer 12e. A ²⁸Si isotope composition ratio of the silicon crystal layer 14e is, e.g., 99.9%. Crystal strains are introduced into the silicon crystal layer 14e.

The semiconductor substrate according to the present embodiment is characterized mainly, as described above, by the strained Si/SiGeOI structure whose insulation film 16a is formed by SIMOX.

Even in a case that the insulation film 16a is formed by SIMOX, because of the silicon germanium crystal layer 12e and the silicon crystal layer 14e having the ²⁸Si isotope composition ratios set high, the thermal conductivities of the silicon germanium crystal layer 12e and the silicon crystal layer 14e can be high. Thus, the semiconductor substrate according to the present embodiment can effectively radiate the heat.

(The Method for Fabricating the Semiconductor Substrate)

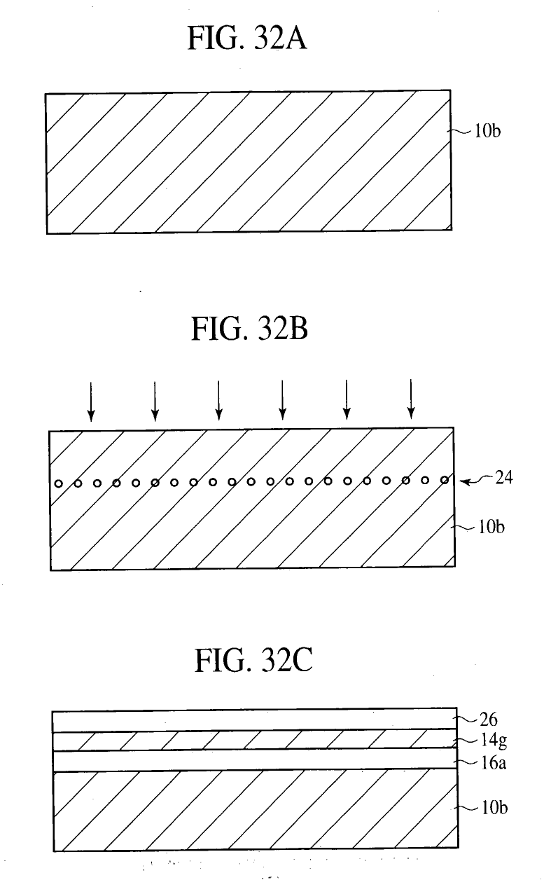

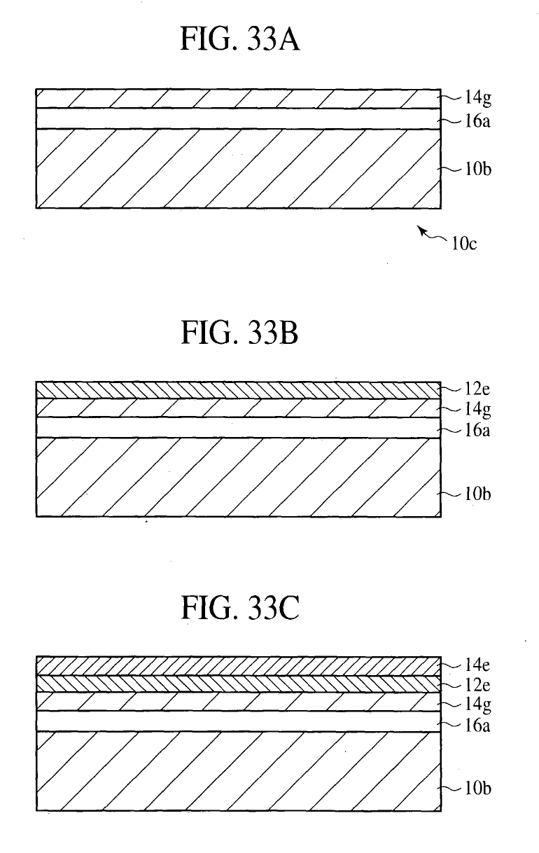

Next, the method for fabricating the semiconductor substrate according to the present embodiment will be explained with reference to FIGS. 32A to 33C. FIGS. 32A to 33C are sectional views of the semiconductor substrate according to the present embodiment in the steps of the method for fabricating the semiconductor substrate, which explain the method.

As shown in FIG.32A, the base substrate 10b of usual silicon crystals having the isotope abundance ratio not controlled is prepared.

Next, as shown in FIG. 32B, oxygen ions are implanted into the entire surface at the surface of the base substrate 10b by ion implantation. Ion implantation conditions are, e.g., 180 keV acceleration energy and a 4×10¹⁷ cm⁻² dose. In the drawing, the region 24 with the oxygen ions implanted in is indicated by circles.

Then, as shown in FIG. 32C, thermal processing is performed in an atmosphere of argon gas and oxygen gas, at 1350° C. and for 5 hours. Thus, the insulation film 16a of SiO₂ is formed in the region 24 with oxygen ions implanted in. The insulation film 16a isolates the silicon crystal layer 14a and the base substrate 10b from each other. A silicon oxide film 26 is formed on the surface of the silicon crystal layer 14a.

Next, as shown in FIG. 33A, the silicon oxide film 26 on the surface of the silicon crystal layer 14a is etched off.

Thus, the SOI substrate 10c with the insulation film 16a buried in is formed by SIMOX.

Then, as shown in FIG. 33B, the silicon germanium crystal layer 12e is epitaxially grown on the entire surface by, e.g., CVD. As a raw material gas of the Si, a raw material gas of a ²⁸Si isotope composition ratio of, e.g., 99.9% is used. As a raw material gas of the Ge, a usual raw material gas having the isotope abundance ratio of Ge not specifically controlled is used. Thus, the silicon germanium crystal layer 12e having a ²⁸Si isotope composition ratio of, e.g., 99.9% is formed. A thickness of the silicon germanium crystal layer is, e.g., 200 nm. A germanium composition of the silicon germanium crystal layer is set to increase gradually from the lower surface to the upper surface. A concentration of the Ge near the lower surface of the silicon germanium crystal layer is, e.g., 0%, and a concentration of the Ge near the upper surface of the silicon germanium crystal layer is, e.g., 30%.

Next, as shown in FIG. 33C, the silicon crystal layer 14e of, e.g., a 20 nm-thickness is epitaxially grown on the silicon germanium crystal layer 12e by, e.g., CVD. As a raw material gas, a raw material gas of a ²⁸Si isotope composition ratio of, e.g., 99.9% is used. Thus, the silicon crystal layer 14e of a ²⁸Si composition ratio of, e.g., 99.9% is formed. Because of the lattice constant difference between the surface of the silicon germanium crystal layer 12e, crystal strains are introduced into the silicon crystal layer 14e.

Thus, the semiconductor substrate according to the present embodiment is fabricated.

(Modification 1)

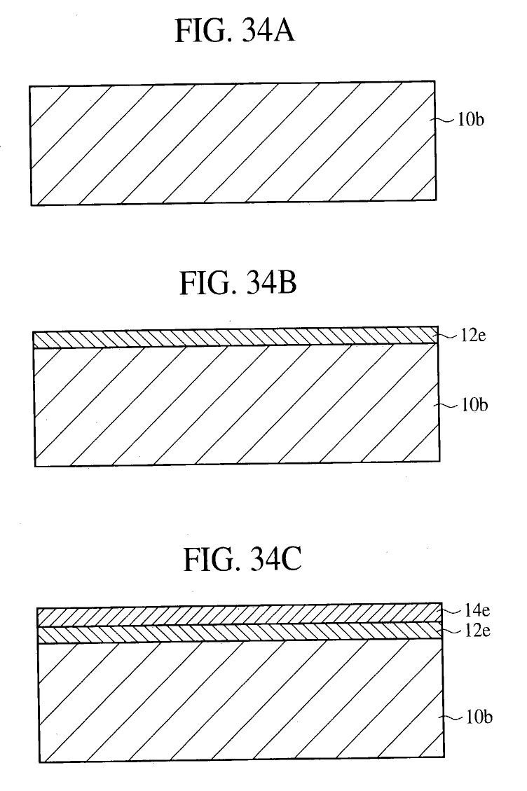

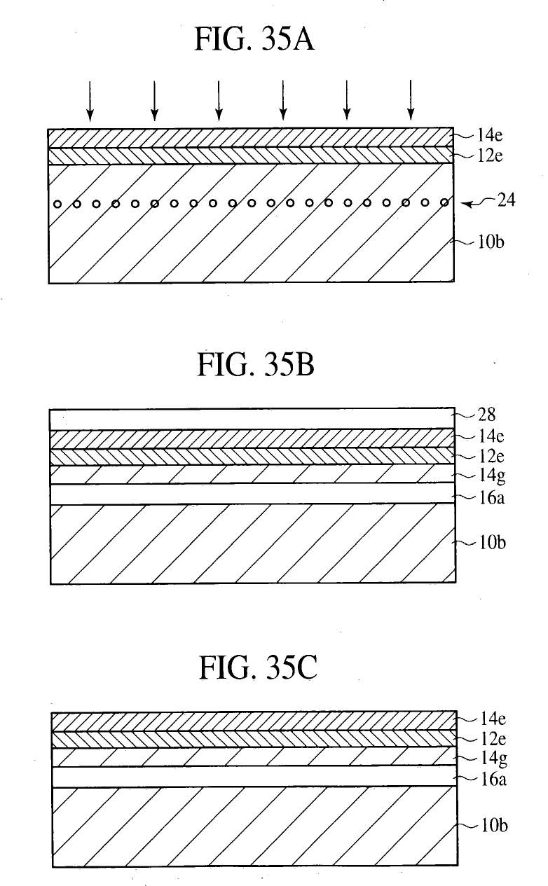

Next, Modification 1 of the method for fabricating the semiconductor substrate according to the present embodiment will be explained with reference to FIGS. 34A to 35C. FIGS. 34A to 35C are sectional views of the semiconductor substrate in the steps of method for fabricating the semiconductor substrate according to the present modification, which explain the method.

The semiconductor substrate fabricating method according to the present modification is characterized mainly in that after a silicon germanium crystal layer 12e and a silicon crystal layer 14e have been formed on a base substrate 10b, an insulation film 16a is formed in the base substrate 12b by SIMOX.

First, as shown in FIG. 34A, the base substrate 10b of usual silicon crystals having the isotope abundance ratio not controlled is prepared.

Next, in the same way as in the method for fabricating the semiconductor substrate described above with reference to FIG. 33B, the silicon germanium crystal layer 12e is epitaxially grown on the base substrate 10b (see FIG. 34B).

Then, in the same way as in the method for fabricating the semiconductor device described above with reference to FIG. 33C, the silicon crystal layer 14e is epitaxially grown on the silicon germanium crystal layer 12e (see FIG. 34C).

Then, as shown in FIG. 35A, oxygen ions are implanted into the base substrate 10b through the silicon crystal layer 14e and the silicon germanium crystal layer 12e. The oxygen ions are implanted in a region which is about 400 nm deep from the surface of the silicon crystal layer 14e. Ion implantation conditions are, e.g., a 180 keV acceleration energy and a 4×10¹⁷ cm⁻² dose. The region 24 with the oxygen ions implanted in is indicated by circles.

Then, as shown in FIG. 35B, thermal processing is performed in an atmosphere containing argon gas and oxygen gas, at 1350° C. and for 5 hours. Thus, the insulation film 16a of SiO₂ is formed in the region 24 with the oxygen ions implanted in. A silicon oxide film 28 is formed on the silicon germanium crystal layer 12e.

Next, as shown in FIG. 35c, the silicon oxide film 28 formed on the silicon germanium crystal layer 12e is etched off.

Thus, the semiconductor substrate according to the present modification is fabricated.

As described above, it is possible that the insulation film 16a is buried in the base substrate 10b by SIMOX after the silicon germanium layer 12e and the silicon crystal layer 14e have been formed on the base substrate 10b.

(Modification 2)

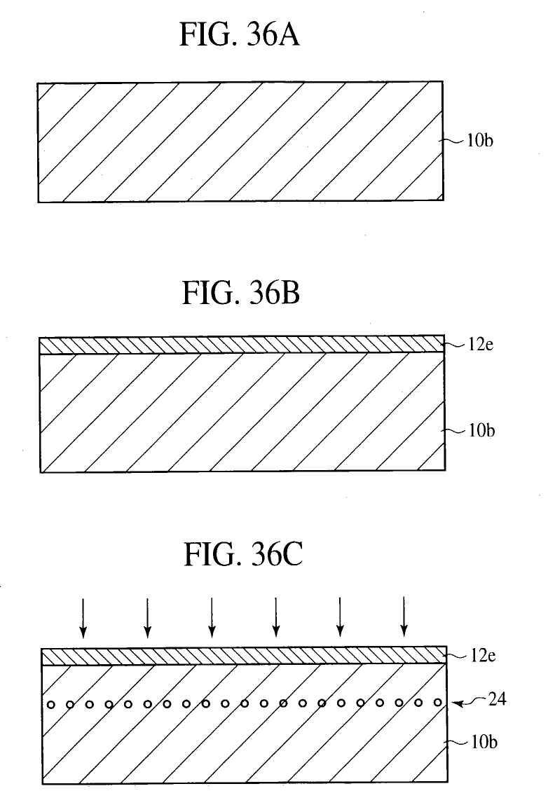

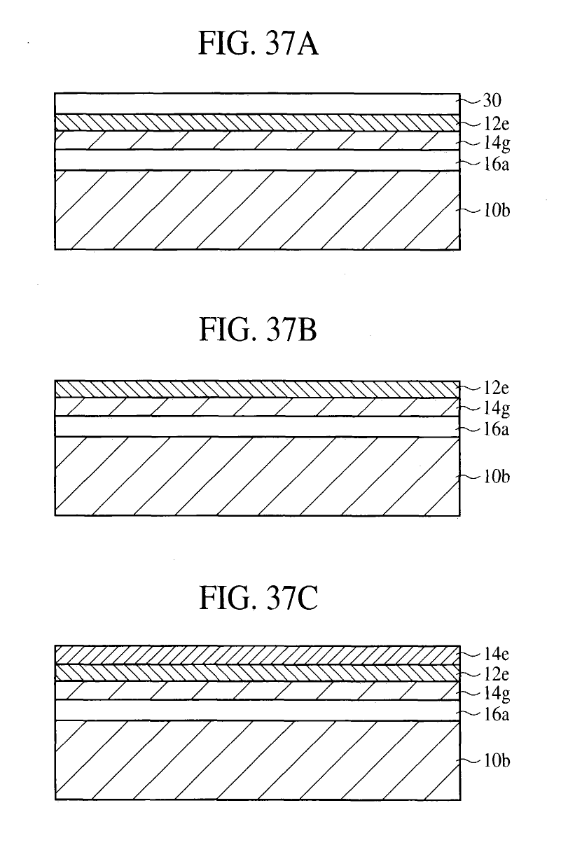

Next, Modification 2 of the method for fabricating the semiconductor substrate according to the present embodiment will be explained with reference to FIGS. 36A to 37C. FIGS. 36A to 37C are sectional views of the semiconductor substrate in the steps of method for fabricating the semiconductor substrate according to the present modification, which explain the method.

The semiconductor substrate fabricating method according to the present modification is characterized mainly in that after the silicon germanium crystal layer 12e has been formed on the base substrate 10b, the insulation film 16b is buried in the base substrate 10b by SIMOX, and then the silicon crystal layer 14e is formed on the silicon germanium crystal layer 12e.

First, as shown in FIG. 36A, the base substrate 10b of usual silicon crystals having the isotope abundance ratio not controlled is prepared.

Next, in the same way as in the semiconductor substrate fabricating method described above with reference to FIG. 33B, the silicon germanium crystal layer 12e is formed (see FIG. 36B) Next, as shown in FIG. 36C, oxygen ions are implanted in the base substrate 10b over the entire surface through the silicon germanium crystal layer 12e by ion implantation. The oxygen ions are implanted in a region which is, e.g., 400 nm deep from the surface of the silicon germanium crystal layer 12e. Ion implantation conditions are, e.g., a 180 keV acceleration energy, and a 4×10¹⁷ cm⁻² dose. In the drawing, the region 24 with the oxygen ions implanted in is indicated by circles.

Next, as shown in FIG. 37A, thermal processing is performed in an atmosphere containing argon gas and oxygen gas, at 1350° C. and a 4×10¹⁷ cm⁻². Thus the insulation film 16a of SiO₂ is formed in the base substrate 10b with the oxygen ions implanted in. A silicon oxide film 30 is formed on the silicon germanium crystal layer 12e.

Next, as shown in FIG. 37B, the silicon oxide film 30 formed on the silicon germanium crystal layer 12e is etched off.

Next, in the same way as in the method for fabricating the semiconductor substrate described above with reference to FIG. 33C, the silicon crystal layer 14e is epitaxially grown on the silicon germanium crystal layer 12e (see FIG. 37C).

Thus, the semiconductor substrate according to the present modification is fabricated.

As described above, it is possible that after the silicon germanium crystal layer 12e has been formed on the base substrate 10b, the insulation film 16a is buried in the base substrate 10b by SIMOX, and then the silicon crystal layer 14e is formed on the silicon germanium crystal layer 12e.

[An Eleventh Embodiment]

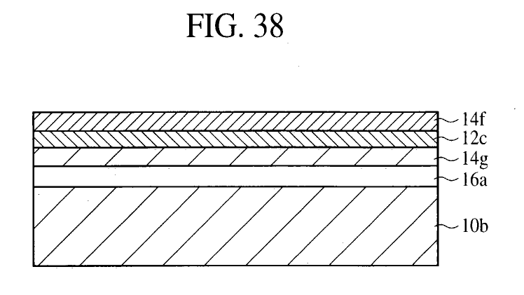

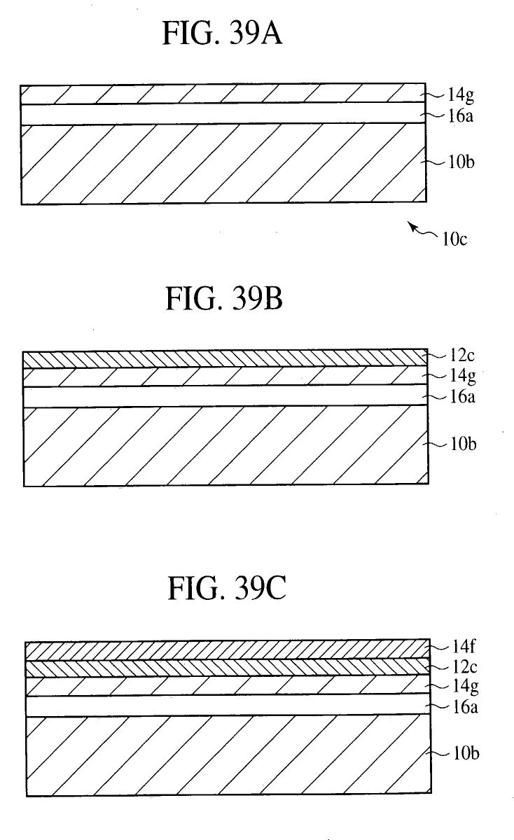

The semiconductor substrate according to an eleventh embodiment of the present invention and the method for fabricating the semiconductor substrate will be explained with reference to FIGS. 38 to 39C. FIG. 38 is a sectional view of the semiconductor substrate according to the present embodiment. The same members of the present embodiment as those of the semiconductor substrate according to the first to the tenth embodiments shown in FIGS. 1 to 37C will be represented by the same reference numbers not to repeat or to simplify their explanation.

(The Semiconductor Substrate)

First, the semiconductor substrate according to the present embodiment will be explained with reference to FIG. 38.

The semiconductor substrate according to the present embodiment is characterized mainly by a strained Si/SiGe structure including a insulation film 16a formed by SIMOX, and a ⁷⁰Ge isotope composition ratio of a silicon germanium crystal layer 12c is set high.

As shown in FIG. 38, the silicon germanium crystal layer 12c is formed on a silicon crystal layer 14g. A ⁷⁰Ge isotope composition ratio of the silicon germanium crystal layer 12c is, e.g., 99.9%. An isotope abundance ratio of the Si of the silicon germanium crystal layer 12c is the same as that of Si in nature. A Ge composition of the silicon germanium crystal layer 12c is set to increase gradually from the lower surface to the upper surface. A concentration of the Ge near the lower surface of silicon germanium crystal layer 12c is, e.g., 0%, and that of the Ge near the upper surface of the silicon germanium crystal layer 12c is, e.g., 30%.

A silicon crystal layer 14f is formed on the silicon germanium crystal layer 12c. An isotope abundance ratio of the Si of the silicon crystal layer 14f is the same as that of Si in nature.

The semiconductor substrate according to the present embodiment is characterized mainly, as described above, by the strained Si/SiGe structure including the insulation film 16a formed by SIMOX and having a ⁷⁰Ge isotope composition ratio of the silicon germanium crystal layer 12c set high.

In the present embodiment, because of a ⁷⁰Ge isotope composition ratio of the silicon germanium crystal layer 12c set high, the silicon germanium crystal layer 12c can have high thermal conductivity. As described above, in the semiconductor substrate of the strained Si/SiGe structure, the semiconductor substrate can have high thermal conductivity by setting a ⁷⁰Ge isotope composition ratio high.

(The Method for Fabricating the Semiconductor Substrate)

Next, the method for fabricating the semiconductor substrate according to the present embodiment will be explained with reference to FIGS. 39A to 39C. FIGS. 39A to 39C are sectional views of the semiconductor substrate according to the present embodiment in the steps of the method for fabricating the semiconductor substrate.

The steps up to the step of fabricating the SOI substrate 10c with the insulation film 16a formed by SIMOX buried in including the SOI substrate 10c fabricating step are the same as those of the semiconductor substrate fabricating method described above with reference to FIGS. 32A to 33A, and their explanation will be not be repeated (see FIG. 39A).

Then, in the same way as in the method for fabricating the semiconductor substrate described above with reference to FIG. 28B, the silicon germanium crystal layer 12c is epitaxially grown on the silicon crystal layer 14g.

Next, in the same way as in the method for fabricating the semiconductor substrate described above with reference to FIG. 28C, the silicon crystal layer 14f is epitaxially grown on the silicon germanium crystal layer 12c.

Thus, the semiconductor substrate according to the present embodiment can be fabricated.

(Modification 1)

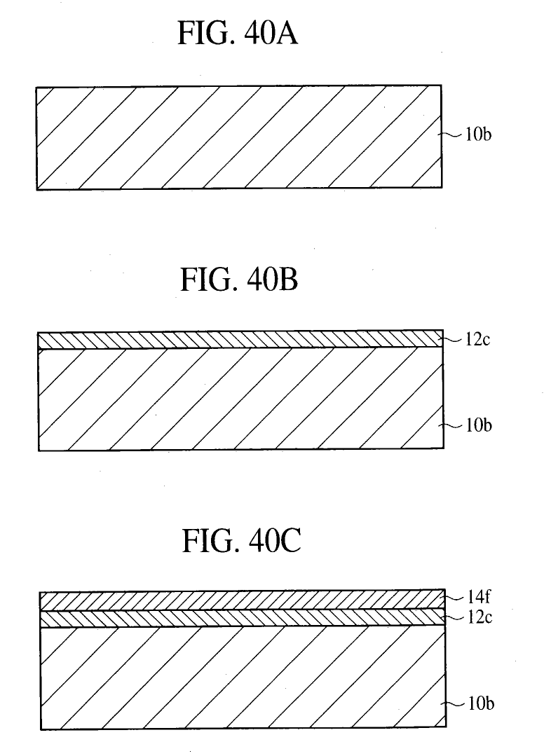

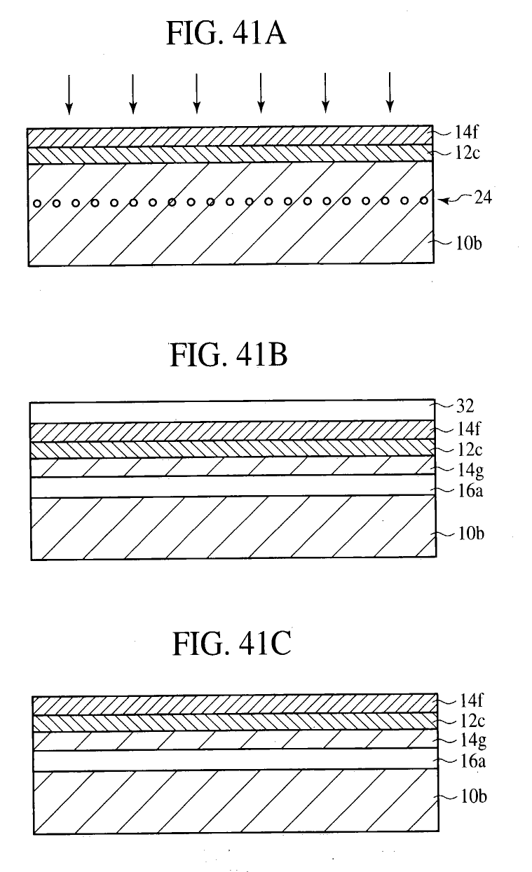

Next, Modification 1 of the method for fabricating the semiconductor substrate according to the present embodiment will be explained with reference to FIGS. 40A to 41C. FIGS. 40A to 41C are sectional views of the semiconductor substrate in the steps of method for fabricating the semiconductor substrate according to the present modification, which explain the method.

The semiconductor substrate fabricating method according to the present modification is characterized mainly in that after the silicon germanium crystal layer 12c and the silicon crystal layer 14f are formed on the base substrate, the insulation film 16a is buried in the base substrate 10b by SIMOX.

First, as shown in FIG. 40A, the base substrate 10b of usual silicon crystals having the isotope abundance ratio not controlled is prepared.

Then, in the same way as in the method fabricating the semiconductor substrate described above with reference to FIG. 28B, the silicon germanium crystal layer 12c is epitaxially grown on the base substrate 10b (see FIG. 40B).

Next, in the same way as in the method for fabricating the semiconductor substrate described above with reference to FIG. 28C, the silicon crystal layer 14f is epitaxially grown on the silicon germanium crystal layer 12c (see FIG. 40C).

Next, as shown in FIG. 41A, oxygen ions are implanted in the entire surface at the surface of the silicon crystal layer 14f by ion implantation. The oxygen ions are implanted in a region which is, e.g., about 400 nm deep from the surface of the silicon crystal layer 14f. Ion implantation conditions are, e.g., a 180 keV acceleration energy and a 4×10¹⁷ cm⁻² dose. In the drawing, the region 24 with the oxygen ions implanted in is indicated by circles.

Next, as shown in FIG. 41B, thermal processing is performed in an atmosphere containing argon gas and oxygen gas, at 1350° C. and 5 hours. Thus, the insulation film 16a of SiO₂ is formed in the region 24 with the oxygen ions implanted in. A silicon oxide film 32 is formed on the silicon germanium crystal layer 14f.

Then, as shown in FIG. 41C, the silicon oxide film 32 formed on the silicon germanium crystal layer 14f is etched off.

Thus, the semiconductor substrate according to the present modification is fabricated.

As described above, it is possible that after the silicon germanium crystal layer 12c and the silicon crystal layer 14f have been formed on the base substrate lob, the insulation film 16a may be buried in the base substrate 10b by SIMOX.

(Modification 2)

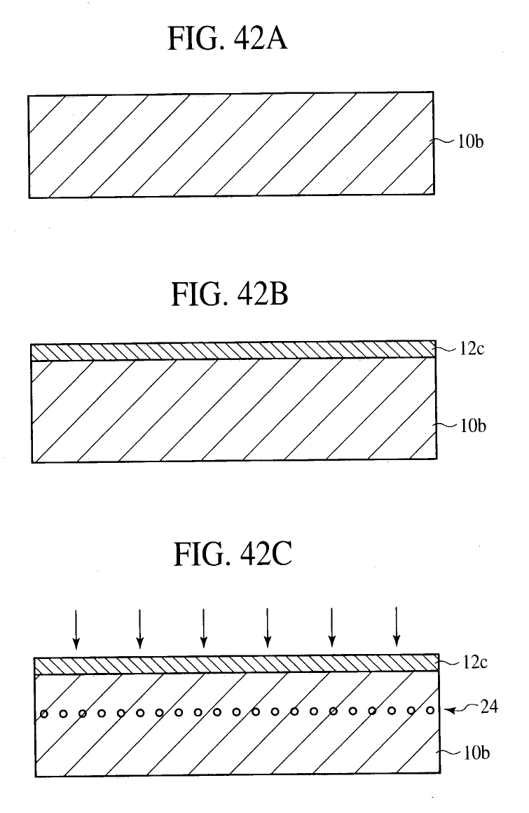

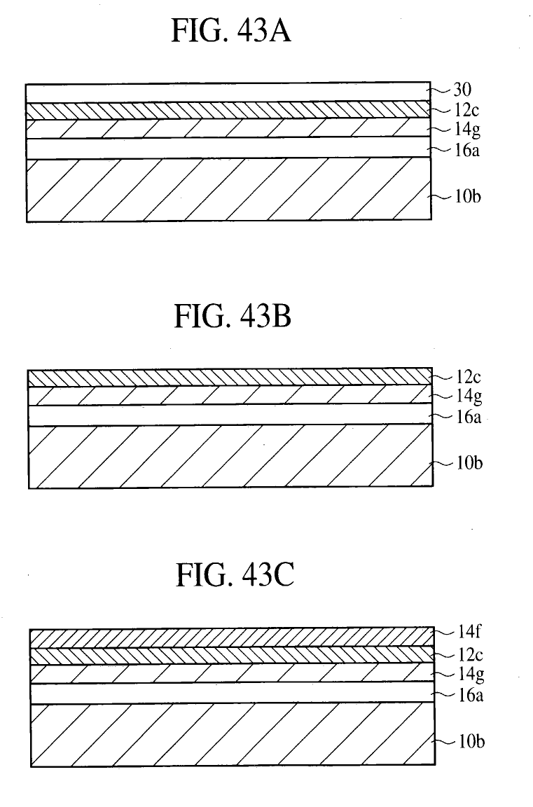

Next, Modification 2 of the method for fabricating the semiconductor substrate according to the present embodiment will be explained with reference to FIGS. 42A to 43C. FIGS. 42A to 43C are sectional views of the semiconductor substrate in the steps of method for fabricating the semiconductor substrate according to the present modification, which explain the method.

The semiconductor fabricating method according to the present modification is characterized mainly in that after the silicon germanium crystal layer 12c has been formed on the base substrate 10b, the insulation film 16a is buried in the base substrate 10b by SIMOX, and then the silicon crystal layer 14f is formed on the silicon germanium crystal layer 12c.

First, as shown in FIG. 42A, the base substrate 10b of usual silicon crystals having the isotope abundance ratio not controlled is prepared.

Next, in the same way as in the semiconductor fabricating method described above with reference to FIG. 28B, the silicon germanium crystal layer 12c is epitaxially formed on the base substrate 10b. (see FIG. 42B).

Next, as shown in FIG. 42C, oxygen ions are implanted in the base substrate 10b over the entire surface through the silicon germanium crystal layer 12c by ion implantation. The oxygen ions are implanted in a region which is, e.g., 400 nm deep from the surface of the silicon germanium crystal layer 12c. Ion implantation conditions are, e.g., a 180 keV acceleration energy and a 4×10¹⁷ cm⁻² dose. In the drawing, the region 24 with the oxygen ions implanted in is indicated by circles.

Then, as shown in FIG. 43A, thermal processing is performed in an atmosphere containing argon gas and oxygen gas, at 1350° C. and for 5 hours. Thus, the insulation film 16a of SiO₂ is formed in the base substrate 10b with the oxygen ions implanted in. A silicon oxide film 30 is formed on the silicon germanium crystal layer 12c.

Next, as shown in FIG. 43B, the silicon oxide film 30 formed on the silicon germanium crystal layer 12c is etched off.

Then, in the same way as in the semiconductor substrate fabricating method described above with reference to FIG. 28C, the silicon crystal layer 14f is epitaxially grown on the silicon germanium crystal layer 12c.

Thus, the semiconductor substrate according to the present modification can be fabricated.

As described above, it is possible that after the silicon germanium crystal layer 12c has been formed on the base substrate 10b, the insulation film 16a is buried in the base substrate 10b by SIMOX, and then the silicon crystal layer 14f is formed on the silicon germanium crystal layer 12c.

[A Twelfth Embodiment]

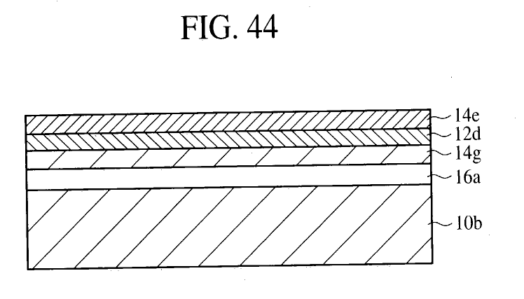

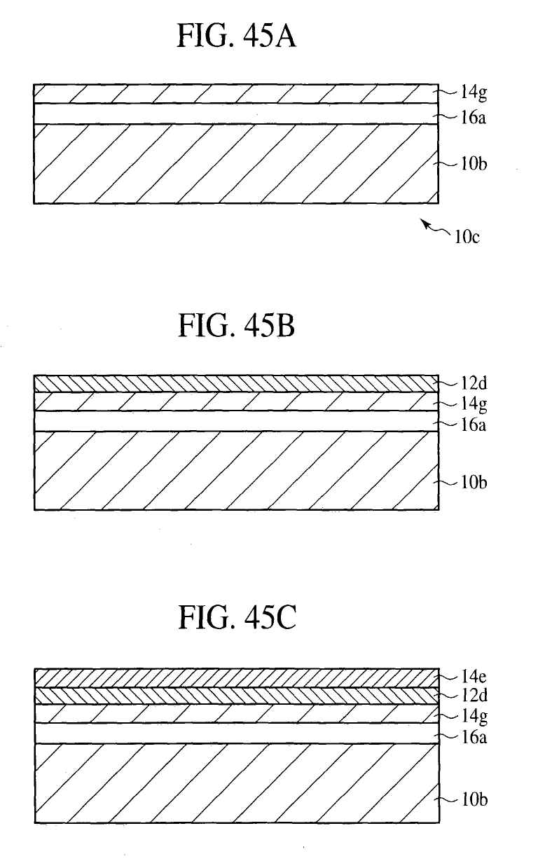

The semiconductor substrate according to a twelfth embodiment of the present invention and the method for fabricating the semiconductor substrate will be explained with reference to FIGS. 44 to 45C. FIG. 44 is a sectional view of the semiconductor substrate according to the present embodiment. The same members of the present embodiment as those of the semiconductor substrate according to the first to the eleventh embodiments and the method for fabricating the semiconductor; device shown in FIGS. 1 to 43C are represented by the same reference numbers not to repeat or to simplify their explanation.

(The Semiconductor Substrate)

First, the semiconductor substrate according to the present embodiment will be explained with reference to FIG. 44.

The semiconductor substrate according to the present embodiment is characterized mainly by a strained Si/SiGe structure having an insulation film 16a buried in a base substrate 10b by SIMOX, having a ²⁸Si isotope composition ratio and a ⁷⁰Ge isotope composition ratio of a silicon germanium crystal layer 12d set high, and having a ²⁸Si isotope composition ratio of a silicon crystal layer 14e set high.

Then, as shown in FIG. 44, the silicon germanium crystal layer 12d is formed on the silicon crystal layer 14g. A ⁷⁰Ge isotope composition ratio of the silicon germanium crystal layer 12d is, e.g., 99.9%. A ²⁸Si isotope composition ratio of the silicon germanium crystal layer 12d is, e.g., 99.9%. A Ge composition of the silicon germanium crystal layer 12d is set to increase gradually from the lower surface to the upper surface. A Ge concentration near the lower surface of the silicon germanium crystal layer 12d is, e.g., 0%, and a Ge concentration near the upper surface of the silicon germanium crystal layer 12d is, e.g., 30%.

The silicon crystal layer 14e is formed on the silicon germanium crystal layer 12d. A ²⁸Si isotope composition ratio of the silicon crystal layer 14e is, e.g., 99.9%. Crystal strains are introduced into the silicon crystal layer 14e.

The semiconductor substrate according to the present embodiment is characterized mainly, as described above, by the strained Si/SiGe structure having the insulation film 16a buried in the base substrate 10b by SIMOX, and having both a ²⁸Si isotope composition ratio and a ⁷⁰Ge isotope composition ratio of the silicon germanium crystal layer 12d set high and having a ²⁸Si isotope composition ratio of the silicon crystal layer 14e set high.

According to the present embodiment, both a ²⁸Si isotope composition ratio and a ⁷⁰Ge isotope composition ratio of the silicon germanium crystal layer 12d are set high, and a ²⁸Si isotope composition ratio of the silicon crystal layer 14e is set high, whereby both the silicon germanium crystal layer 12d and the silicon crystal layer 14e can have high thermal conductivity. Accordingly, the semiconductor substrate according to the present embodiment can effectively radiate the heat.

(The Method for Fabricating the Semiconductor Substrate)

Then, the method for fabricating the semiconductor substrate according to the present embodiment will be explained with reference to FIGS. 45A to 45C. FIGS. 45A to 45C are sectional views of the semiconductor substrate according to the present embodiment in the steps of the method for fabricating the semiconductor substrate, which explain the method.

First, the steps up to the step of fabricating by SIMOX the SOI substrate 10c with the insulation film 16a buried in including the SOI substrate fabricating step are the same as those of the semiconductor fabricating method described above with reference to FIGS. 32A to 33A, and their explanation will not be repeated (see FIG. 45A).

Then, in the same way as in the semiconductor substrate fabricating method described above with reference to FIG. 30B, the silicon germanium crystal layer 12d is epitaxially grown on the silicon crystal layer 14g.

Then, in the same way as in the semiconductor substrate fabricating method described above with reference to FIG. 30C, the silicon crystal layer 14e is epitaxially grown on the silicon germanium crystal layer 12d.

Thus, the semiconductor substrate according to the present embodiment is fabricated.

(Modification 1)

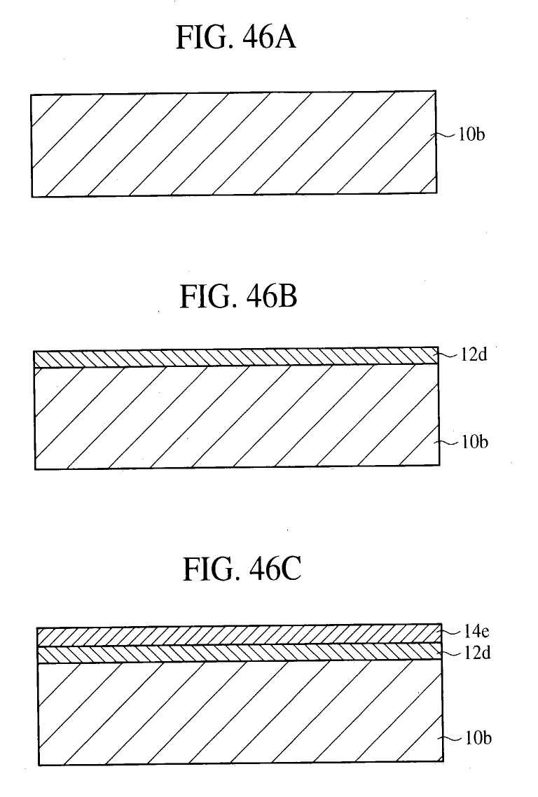

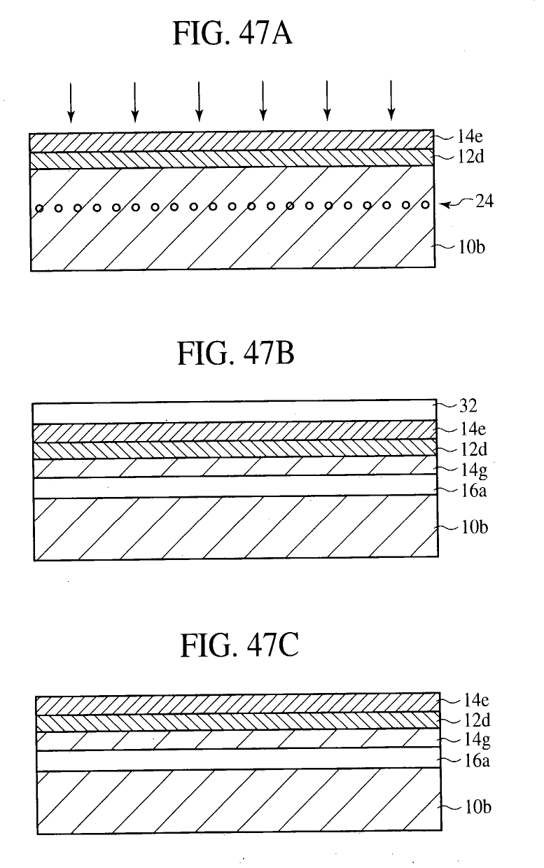

Next, Modification 1 of the method for fabricating the semiconductor substrate according to the present embodiment will be explained with reference to FIGS. 46A to 47C. FIGS. 46A to 47C are sectional views of the semiconductor substrate in the steps of method for fabricating the semiconductor substrate according to the present modification, which explain the method.

The semiconductor fabricating method according to the present modification is characterized mainly in that after the silicon germanium crystal layer 12d and the silicon crystal layer 14e have been formed on the base substrate 10b, the insulation film 16a is buried in the base substrate 10b by SIMOX.

First, as shown in FIG. 46A, the base substrate 10b of usual silicon crystals having the isotope abundance ratio not controlled is prepared.

Then, in the same way as in the semiconductor substrate fabricating method described above with reference to FIG. 30B, the silicon germanium crystal layer 12d is epitaxially grown on the base substrate lob.

Next, in the same way as in the semiconductor substrate fabricating method described above with reference to FIG. 30C, the silicon crystal layer 14e is epitaxially grown on the silicon germanium crystal layer 12d.

Next, as shown in FIG. 47A, oxygen ions are implanted into the base substrate 10b over the entire surface through the silicon crystal layer 14e and the silicon germanium crystal layer 14e by ion implantation. The oxygen ions are implanted in a region which is about 400 nm deep from the surface of the silicon crystal layer 14e. Ion implantation conditions are, e.g., a 180 keV acceleration energy and a 4×10¹⁷ cm⁻² dose. The region 24 with the oxygen ions implanted in is indicated by circles.

Next, as shown in FIG. 47B, thermal processing is performed in an atmosphere containing argon gas and oxygen gas, at 1350° C. and for 5 hours. Thus, the insulation film 16a of SiO₂ is formed in the base substrate 10b with the oxygen ions implanted in. A silicon oxide film 32 is formed on the silicon crystal layer 14e.

The following semiconductor fabricating process is the same as that of the semiconductor substrate fabricating method described above with reference to FIG. 41C, and its explanation will not be repeated (see FIG. 47C).

Thus, the semiconductor substrate according to the present modification is fabricated.

As described above, it is possible that after the silicon germanium crystal layer 12d and the silicon layer 14e have been formed on the base substrate 10b, the insulation film 16a is buried in the base substrate 12b by SIMOX.

(Modification 2)

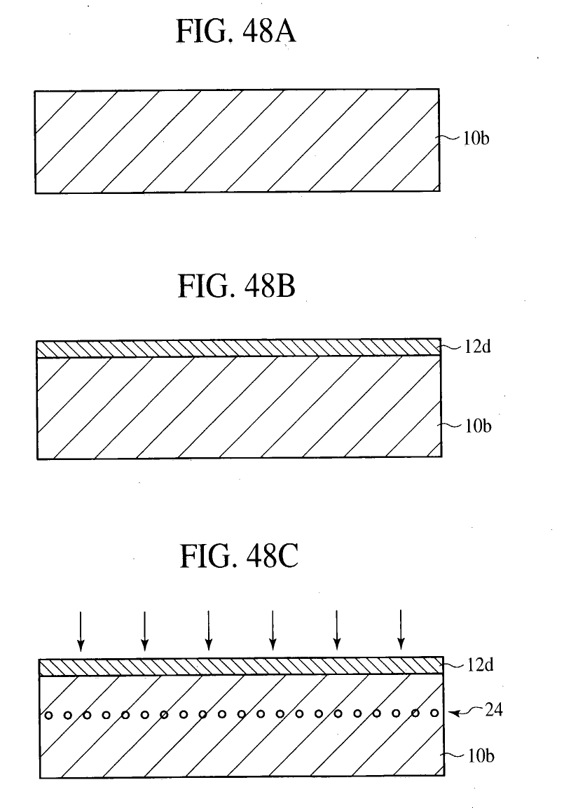

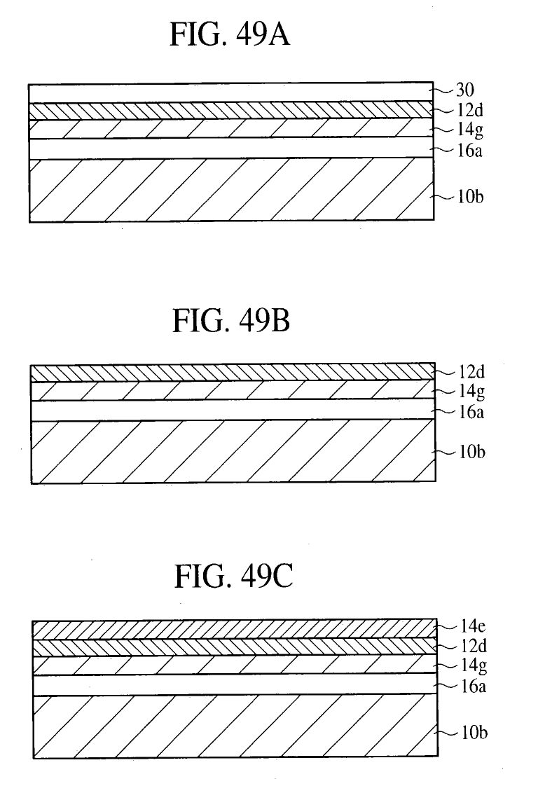

Next, Modification 2 of the method for fabricating the semiconductor substrate according to the present embodiment will be explained with reference to FIGS. 48A to 49C. FIGS. 48A to 49C are sectional views of the semiconductor substrate in the steps of method for fabricating the semiconductor substrate according to the present modification, which explain the method (Part 2).

The semiconductor substrate fabricating method according to the present modification is characterized mainly in that after the silicon germanium crystal layer 12d has been formed on the base substrate 10b, the insulation film 16a is formed in the base substrate 10b by SIMOX, and then the silicon crystal layer 14e is formed on the silicon germanium crystal layer 12d.

First, as shown in FIG. 48A, the base substrate 10b of usual silicon crystals having the isotope abundance ratio not controlled is prepared. Next, in the same way as in the semiconductor substrate fabricating method described above with reference to FIG. 30B, the silicon germanium crystal layer 12d is epitaxially grown on the base substrate 10b.

Next, as shown in FIG. 30C, oxygen ions are implanted in the base substrate 10b over the entire surface through the silicon germanium crystal layer 12d by ion implantation. The oxygen ions are implanted in a region which is, e.g., 400 nm deep from the surface of the silicon germanium crystal layer 12d. Ion implantation conditions are, e.g., a 180 keV acceleration energy and a 4×10¹⁷ cm⁻² dose. In the drawing, the region 24 with the oxygen ions implanted in is indicated by circles.

Then, as shown in FIG. 49A, thermal processing is performed in an atmosphere containing argon gas and oxygen gas, at 1350° C. and for 5 hours. Thus, the insulation film 16a of SiO₂ is formed in the base substrate 10b with the oxygen ions implanted in. A silicon oxide film 30 is formed on the silicon germanium crystal layer 12d.

Next, as shown in FIG. 49B, the silicon oxide film 30 formed on the silicon germanium crystal layer 12d is etched off.

Then, as shown in FIG. 49C, the silicon crystal layer 14e is epitaxially grown on the silicon germanium crystal layer 12d, Thus, the semiconductor substrate according to the present modification can be fabricated.

As described above, it is possible that after the silicon germanium crystal layer 12d has been formed on the base substrate 10b, the insulation film 16 is buried in the base substrate 10b by SIMOX, and then the silicon crystal layer 14e is formed on the silicon germanium crystal layer 12d.

[Modified Embodiments]

The present invention is not limited to the above-described embodiments and can cover other various modifications.

For example, in the above-described embodiments, the ²⁸Si isotope composition ratio is set high but is not essentially set high. The ²⁹Si or ³⁰Si isotope composition ratios may be set high. That is, the isotope composition ratio of any one of ²⁸Si, ²⁹Si and ³⁰Si is set high, whereby the thermal conductivity can be higher.

In the above-described embodiments, the isotope composition of ⁷⁰Ge is set high but is not essentially set high. The isotope composition ratios of ⁷²Ge, ⁷³Ge, ⁷⁴Ge or ⁷⁶Ge may be set high. The isotope composition ratio of any one of ⁷⁰Ge, ⁷²Ge, ⁷³Ge, ⁷⁴Ge and ⁷⁶Ge is set high, whereby the thermal conductivity can be higher.

In the above-described embodiments, the isotope composition ratio of any one of the Si isotopes and the isotope composition ratio of any one of the Ge isotopes are set to be 99.9% but are not essentially set to be 99.9%. They may be set so that a required thermal conductivity can be obtained. However, the isotope composition ratios are set to be above 95%, whereby the thermal conductivity can be much increased. It is preferable to set the isotope compositions ratios to be above 95%. The isotope composition ratios are set to be above 98%, whereby the thermal conductivity can be more increased. It is preferable to set the isotope composition ratios to be above 98%.

In the above-described embodiments, the composition of the silicon germanium crystal layers 12, 12a is Si_{0.7}Ge_{0.3} but is not essentially Si_{0.7}Ge_{0.3}. The compositions of the silicon germanium crystal layers 12, 12a are suitably set so that the silicon crystal layers 14, 14a formed on the silicon germanium layers 14, 14a are suitably strained.

In the above-described embodiments, the plane orientation of the surface of the silicon crystal layer is {100}, {113} or {011}. The plane orientation of the silicon crystal layer is not essentially {100}, {113} or {011} and may be suitably set.

In the above-described embodiments, in the silicon crystal layer and the silicon germanium crystal layer, the isotope composition ratio of any one of the Si isotopes and the isotope composition ratio of any one of the Ge isotopes are set high. However, in the silicon crystal substrate and the silicon germanium crystal substrate, the isotope composition ratio of any one of the Si isotope composition ratios and the isotope composition ratio of any one of the Ge isotope composition ratios may be set high. That is, in at least any one of the silicon crystal layer, the silicon germanium crystal layer, the silicon crystal substrate and the silicon germanium crystal substrate, the isotope composition ratio of any one of the Si isotopes, the isotope composition ratio of any one of the Ge isotopes are set high, whereby the semiconductor substrate can effectively radiate the heat. In all of the silicon crystal layer, the silicon germanium crystal layer, the silicon crystal substrate, etc., the isotope composition ratio of any one of the Si isotopes and the isotope composition ratio of any one of the Ge isotopes may be set high, whereby the semiconductor substrate can more effectively radiate the heat.

In the seventh and the eleventh embodiments, the insulation film is formed below the silicon germanium crystal layer but is not essentially formed below the silicon germanium crystal layer. For example, the insulation film may be buried in the silicon germanium crystal layer.

What is claimed is:

1. A semiconductor substrate comprising a silicon substrate; a silicon germanium layer formed on the silicon substrate; and a silicon layer formed on the silicon germanium layer,
at least one of an isotope composition ratio of one Si isotope and an isotope composition ratio of one Ge isotope of at least one of the silicon substrate, the silicon germanium layer and the silicon layer being above 95%.

2. A semiconductor substrate comprising a silicon germanium substrate; and a silicon layer formed on the silicon germanium substrate,
at lest one of an isotope composition ratio of one Si isotope and an isotope composition ratio of one Ge isotope of at least one of the silicon germanium substrate and the silicon layer being above 95%.

3. A semiconductor substrate comprising a base substrate and a silicon layer bonded to each other with an insulation film formed therebetween,
an isotope composition ratio of one Si isotope of at least one of the base substrate and the silicon layer being above 95%.

4. A semiconductor substrate according to claim 3, wherein
carbon atoms are implanted in the silicon layer nearer to the interface between the silicon layer and the insulation film.

5. A semiconductor substrate according to claim 4, wherein
the carbon atoms are implanted so that a concentration of the carbon atoms can be above 1×10²⁰ cm⁻³ and below 1×10²¹ cm⁻³.

6. A semiconductor substrate comprising a base substrate; a silicon germanium layer formed on the base substrate with an insulation film formed therebetween; and a silicon layer formed on the silicon germanium layer,
one of an isotope composition ratio of one Si isotope and an isotope composition ratio of one Ge isotope of at least one of the silicon germanium layer and the silicon layer being above 95%.

7. A semiconductor substrate according to claim 1, wherein
a plane orientation of the surface of the silicon layer is {100}, {113} or {011}.

8. A semiconductor substrate according to claim 2, wherein
a plane orientation of the surface of the silicon layer is {100}, {113} or {011}.

9. A semiconductor substrate according to claim 3, wherein
a plane orientation of the surface of the silicon layer is {100}, {113} or {011}.

10. A semiconductor substrate according to claim 6, wherein
a plane orientation of the surface of the silicon layer is {100}, {113} or {011}.

11. A method for fabricating a semiconductor substrate comprising the steps of:
forming a silicon germanium layer on a silicon substrate, and
forming a silicon layer on the silicon germanium layer,
the silicon germanium layer or the silicon layer being formed by using a raw material gas in which at least one of an isotope composition ratio of one Si isotope and an isotope composition ratio of one Ge isotope is above 95% in at least one of the step of forming a silicon germanium layer and the step of forming a silicon layer.

12. A method for fabricating a semiconductor substrate comprising the step of forming a silicon layer on a silicon germanium substrate,
the silicon layer being formed by using a raw material gas having an above 95% isotope composition ratio of one Si isotope in the step of forming the silicon layer.

13. A method for fabricating a semiconductor substrate comprising the step of:
forming an insulation film on one surface of a silicon substrate having an above 95% isotope composition ratio of one Si isotope;
bonding the insulation film to a base substrate; and
thinning the silicon substrate at the other surface of the silicon substrate.

14. A method for fabricating a semiconductor substrate according to claim 13, further comprising
the step of implanting carbon atoms into a region of the silicon substrate nearer to said one surface thereof before the step of forming the insulation film.

15. A method for fabricating a semiconductor substrate according to claim 13, further comprising
the step of implanting carbon atoms into the silicon substrate nearer to the interface between the silicon substrate and the insulation film after the step of forming the insulation film and before bonding the insulation film to the base substrate.

16. A method for fabricating a semiconductor substrate according to claim 13, further comprising
the step of implanting carbon atoms into the silicon layer nearer to the interface between the silicon layer of said thinned silicon substrate and the insulation film after the step of thinning the silicon substrate.

17. A method for fabricating a semiconductor substrate comprising the steps of:
forming a silicon layer on one surface of a silicon substrate by using a raw material gas having an 95% isotope composition ratio of one Si isotope;
forming an insulation film on the silicon layer;
bonding a base substrate to the insulation film; and
thinning the silicon substrate at the other surface of the silicon substrate.

18. A method for fabricating a semiconductor substrate according to claim 17, further comprising
the step of implanting carbon atoms into the silicon layer near the surface thereof after the step of forming the silicon layer and before the step of forming the insulation film.

19. A method for fabricating a semiconductor substrate according to claim 17, further comprising
the step of implanting carbon atoms into the silicon layer nearer to the interface between the silicon layer and the insulation film after the step of forming the insulation film and before the step of bonding the base substrate.

20. A method for fabricating a semiconductor substrate according to claim 17, further comprising
the step of implanting carbon atoms into the silicon layer nearer to the interface between the silicon layer and the insulation film after the step of thinning the silicon substrate.

21. A method for fabricating a semiconductor substrate comprising the steps of:
bonding a silicon substrate to a base substrate with an insulation film formed therebetween,
thinning the silicon substrate on the side of the silicon substrate;
forming a silicon germanium layer on said thinned silicon substrate; and
the step of forming a silicon layer on the silicon germanium layer,
the silicon germanium layer or the silicon layer being formed by using a raw material gas in which at least one of an isotope composition ratio of one Si isotope and an isotope composition ratio of one Ge isotope is above 95% in at least one of the step of forming a silicon germanium layer and the step of forming a silicon layer.

22. A method for fabricating a semiconductor substrate comprising the steps of:
burying an insulation film in a silicon substrate;
forming a silicon germanium layer on the silicon substrate with the insulation film buried in; and
forming a silicon layer on the silicon germanium layer,
the silicon germanium layer or the silicon layer being formed by using a raw material gas in which at least an isotope composition ratio of one Si isotope and an isotope composition ratio of one Ge isotope is above 95% in at least one of the step of forming a silicon germanium layer and the step of forming a silicon layer.

23. A method for fabricating a semiconductor substrate comprising the steps of:
forming a silicon germanium layer on a silicon substrate;
forming a silicon layer on the silicon germanium layer; and
burying an insulation film in the silicon substrate,
the silicon germanium layer or the silicon layer being formed by using a raw material gas in which at least one of an isotope composition ratio of an Si isotope and an isotope composition ratio of a Ge isotope is above 95% in at lest one of the step of forming a silicon germanium layer and the step of forming a silicon layer.

24. A method for fabricating a semiconductor substrate comprising the steps of:
forming a silicon germanium layer on a silicon substrate;
burying an insulation film in the silicon substrate; and
forming a silicon layer on the silicon germanium layer,
the silicon germanium layer or the silicon layer being formed by using a raw material gas in which at least one of an isotope composition ratio of an Si isotope and an isotope composition ratio of a Ge isotope is above 95% in at least one of the step of forming a silicon germanium layer and the step of forming a silicon layer.
